(19) United States
(12) Patent Application Publication
(10) Pub. No.: US 2023/0377831 A1
(43) Pub. Date: Nov. 23, 2023

(54) ANTI-SCANNING OPERATION MODE OF SECONDARY-ELECTRON PROJECTION IMAGING SYSTEM FOR APPARATUS WITH PLURALITY OF BEAMLETS

(71) Applicant: ASML Netherlands B.V., Veldhoven (NL)

(72) Inventors: Oleg KRUPIN, Mountain View, CA (US); Weiming REN, San Jose, CA (US); Xuerang HU, San Jose, CA (US); Xuedong LIU, San Jose, CA (US)

(73) Assignee: ASML Netherlands B.V., Veldhoven (NL)

(21) Appl. No.: 18/027,903

(22) PCT Filed: Sep. 2, 2021
(86) PCT No.: PCT/EP2021/074216

§ 371 Date: Mar. 22, 2023

Related U.S. Application Data
(60) Provisional application No. 63/081,715, filed on Sep. 22, 2020.

(51) Int. Cl. H01J 37/147; H01J 37/244; H01J 37/21

(52) U.S. Cl. CPC H01J 37/1472; H01J 37/244; H01J 37/21; H01J 37/28

(57) ABSTRACT

A method of operating a secondary imaging system of a charged particle beam apparatus may include using an anti-scanning mode. Excitation of a component of the secondary imaging system may be adjusted synchronously with a primary scanning deflection unit. Together with an anti-scanning deflection unit performing anti-scanning, a component of the secondary imaging system, such as a lens, may be adjusted in step. As scanning and anti-scanning is performed, excitation parameters of the component may also be constantly updated.

### CROSS-REFERENCE TO RELATED APPLICATIONS

This application claims priority of U.S. application 63/081,715 which was filed on 22 Sep. 2020, and which is incorporated herein in its entirety by reference.

### FIELD

The description herein relates to a charged-particle apparatus that may have a plurality of charged-particle beams. More particularly, it relates to an apparatus which employs plural charged-particle beams (beamlets) to simultaneously acquire images of plural scanned regions of an observed area on a sample surface. Such an apparatus may be used to inspect or review defects on wafers or masks with high resolution and high throughput useful in the semiconductor manufacturing industry.

### BACKGROUND

In manufacturing processes of integrated circuits (ICs), unfinished or finished circuit components may be inspected to ensure that they are manufactured according to design and are free of defects. Inspection may be done by a charged particle beam system that scans (e.g., deflects) a primary beam across a sample and collects secondary particles generated from the sample at a detector. One example of a charged particle beam system is a scanning electron microscope (SEM). SEMs use beams of electrons because such beams can be used to see structures that are too small to be seen by optical microscopes, such as microscopes using visible light.

Some SEM systems may use multiple beams (e.g., beamlets) to improve throughput. Multiple primary beams may be scanned across sub-regions on the sample, and multiple beams of secondary particles may be generated from the sample and directed to a secondary imaging system. The secondary imaging system may perform anti-scanning to account for adjustment of positions of the secondary beams due to the scanning of the primary beams. However, components in the secondary imaging system may not properly account for scanning and anti-scanning of beams. For example, components in the secondary imaging system including lenses and aberration compensation elements may be optimized only for an undeflected position of the beams. When beams are deflected due to scanning or anti-scanning, beam spots on a detector may be defocused, and imaging quality may be degraded.

### SUMMARY

Embodiments of the present disclosure provide systems and methods for imaging based on charged particle beams. In some embodiments, there may be provided a method of adjusting focus or controlling aberration in a secondary imaging system. The method may include correcting focus of secondary beamlets defocused due to anti-scanning deflection. The method may include adjusting an excitation of a component of a secondary imaging system based on a deflection of an anti-scanning deflector.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a schematic diagram illustrating an exemplary electron beam inspection (EBI) system, consistent with embodiments of the present disclosure.

FIG. 2 is a diagram illustrating a charged particle beam apparatus that may be an example of an electron beam tool, consistent with embodiments of the present disclosure that may be a part of the exemplary electron beam inspection system of FIG. 1.

FIGS. 3A-3G are examples of an enlargement of portions of a secondary column, consistent with embodiments of the present disclosure.

FIG. 4A and FIG. 4B show side views of a portion of a primary electron column with scanning deflection being applied, consistent with embodiments of the present disclosure.

FIG. 5A and FIG. 5B show top views of sample with scanning deflection being applied, consistent with embodiments of the present disclosure.

FIG. 6 illustrates a scan area and scan path, consistent with embodiments of the present disclosure.

FIG. 7A, FIG. 7B, and FIG. 7C illustrate projection of beam spot images on detector cells of a detector, consistent with embodiments of the disclosure.

FIG. 8A and FIG. 8B illustrate beam spots of circular shape, consistent with embodiments of the disclosure.

FIG. 9A and FIG. 9B illustrate beam spots of a shape other than circular, consistent with embodiments of the disclosure.

FIG. 10A and FIG. 10B illustrate beam spots of a shape other than circular, and detector cells in an offset pattern, consistent with embodiments of the disclosure

FIG. 11A and FIG. 11B illustrate beam spots that may have asymmetrical distribution, consistent with embodiments of the disclosure.

FIG. 12 illustrates an approach of determining detector cell shape and size, consistent with embodiments of the disclosure.

FIG. 13 is a flowchart illustrating an exemplary method of correcting focus of a beam, consistent with embodiments of the present disclosure.

FIG. 14 a flowchart illustrating an exemplary method of optimizing a parameter of a beam spot or detector cell, consistent with embodiments of the present disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a thumbnail and yet may include over 2 billion transistors, the size of each transistor being less than 1/1,000th the size of a human hair.

Making these extremely small ICs is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

An image of a wafer may be formed by scanning a primary beam of a SEM system over the wafer and collecting particles (e.g., secondary electrons) generated from the wafer surface at a detector. The process of imaging may include focusing the primary beam to a point, and deflecting (e.g., bending) the beam so that it passes over regions of the wafer in a line-by-line pattern (e.g., a raster scan). At a given time, the beam may be focused to a particular position on a wafer, and output of the detector at this time may be correlated to that particular position on the wafer. An image may be reconstructed based on detector output at each time along the beam scan path.

Inspecting a wafer using a single primary beam of a SEM system may be time consuming. To improve throughput, a multi-beam SEM system may be used. Instead of only a single beam that scans across the wafer, multiple primary beams (e.g., beamlets) may be formed in an array (e.g., a grid pattern) and may scan across the wafer together. Multiple beams of secondary particles may be generated at the wafer, and the secondary particles may be directed to a detector via a secondary imaging system. The detector in a multi-beam system may include an array of detector cells (e.g., different subregions of a detector, or different groups of sensing elements), each configured to receive secondary particles associated with one of the multiple beams.

In a multi-beam system, as the multiple primary beams scan across the wafer, positions of the multiple beams of secondary particles may be shifted, such as by deflectors that deflect the beams to accomplish the scan across the wafer. An anti-scanning deflector may be provided in a secondary imaging system to compensate for this shift and to minimize image displacement on the detector. That is, as the primary beams are deflected by scanning, the beams of secondary particles are deflected back by deflectors of the secondary imaging system by a process called “anti-scanning.” These anti-scanning deflectors may help to keep secondary particles of each beam to be received in its respective detector cell (e.g., keep a one-to-one correspondence between the beam and detector cell).

The secondary imaging system may be provided between the wafer and the detector, and may include components that help to improve image quality. For example, there may be a zoom lens for adjusting magnification so that beam spots are formed with a proper size on detector cells, an anti-rotation lens that adjusts beam rotational positions, and aberration compensation elements that compensate for various aberrations. However, such components are typically fixed to a particular operation state during scanning. They may be set to provide the best average performance for the multiple beams for the whole scanning process and are not adjusting during scanning.

However, while scanning is being performed, properties of the multiple beams may be changing, even when anti-scanning is also performed. For example, origination positions of the beams of secondary particles are constantly changing during scanning, and paths of the beams toward the detector also change. Thus, although components in the secondary imaging system may be set for a base state (e.g., being optimized for an average state or a non-deflected state), some degradation of image quality may occur during scanning because the beams may temporarily be in a state that the secondary imaging system was not set or optimized for. Such degradation may be more pronounced at the extremities of the scan range. For example, in a raster scan pattern, deflection of beams may be at a maximum at the corners of the pattern. Meanwhile, the components of the secondary imaging system may be optimized for focusing the beams when the beams are at a central (undeflected) position, or may be optimized for an average of deflected states. With the secondary imaging system configured in this manner, distorted beam spots may be formed on the detector when the beams are deflected (e.g., at various stages of scanning). Such distortion may lead to low collection efficiency (e.g., the proportion of secondary particles collected to those generated), and undesirable cross-talk (e.g., a situation where particles of different beams are comingled).

To enhance performance of a SEM system, it would be desirable to compensate for different properties of multiple beams in a secondary imaging system while the multiple beams are being scanned across the surface of a sample.

Embodiments of the disclosure may address issues such as those discussed above by operating components of a secondary imaging system such that they are adjusted in step with scanning of the primary beams. Components of the secondary imaging system may be adjusted synchronously with a scanning deflector or an anti-scanning deflector. For example, together with anti-scanning, the secondary imaging system may adjust excitation to other components, such as a zoom lens, projection lens, or aberration compensation elements. Adjustment of components of the secondary imaging system may be done together with anti-scanning performed by an anti-scanning deflector, and thus, the adjusting of components of the secondary imaging system may be referred to as an “anti-scanning mode” of the secondary imaging system.

Beams may be deflected due to scanning, and their properties may change. Together with this, the secondary imaging system may adjust excitation applied to various components in the secondary imaging system based on the deflection so that imaging conditions at any given scan position are improved or even optimal. Beam spots may be formed on the detector with improved imaging quality. For example, beam spots may be formed in a way that avoids or reduces undesirable distortion, or so that a desired shape is achieved. Beam spots may be formed such that secondary particles from the beams are contained in a detector cell. Collection efficiency may be improved as a greater proportion of secondary particles reach the intended detector cell. Furthermore, cross-talk may be reduced, as secondary particles of one beam are prevented from reaching the detector cell associated with a different beam.

In some embodiments, optimization of beam spots on a detector surface may target a particular shape that may deviate from circular, such as an elliptical shape. A detector cell may be square-shaped, and a typical target beam spot may be circular in order to ensure that the beam spot fits within the detector cell. However, when multiple detector cells are provided, for example in a multi-beam system, distortion of some of the beam spots may cause circular-shaped beam spots to deform and may lead to negative effects such as poor collection efficiency and cross-talk, as discussed above. On the other hand, an elliptical shape of a beam spot may help to maximize collection efficiency and minimize cross-talk. The orientation of the elliptical shape may be diagonal. For example, the elliptical shape may be oriented in the diagonal of a square-shaped detector cell. The orientation may be based on the arrangement of neighboring detector cells. A secondary imaging system may be configured to make beam spots have an elliptical shape. The “anti-scanning mode” of the secondary imaging system may target an elliptical shape of beam spots on the detector surface. Embodiments may enhance collection efficiency and reduce or eliminate cross-talk for a detector.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing systems and methods in systems utilizing electron beams (“e-beams”). However, the disclosure is not so limited. Other types of charged particle beams may be similarly applied. Furthermore, systems and methods related to anti-scanning may be used in other imaging systems, such as optical imaging, photon detection, x-ray detection, ion detection, etc. Also, distortion control or beam projection may be applicable in other systems, such as lithography systems. Additionally, the term “beamlet” may refer to a constituent part of a beam or a separate beam extracted from an original beam. The term “beam” may refer to beams or beamlets.

The term “detector cell” may refer to a portion of a detector. An individual detector cell may be configured to detect charged particles associated with one beamlet. A detector may be pixelated, having a plurality of sensing elements in an array pattern. One or more of the sensing elements may be grouped together and form a detector cell. A sensing element may refer to a semiconductor diode making up the detector. A subregion of a detection may correspond to a detector cell.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

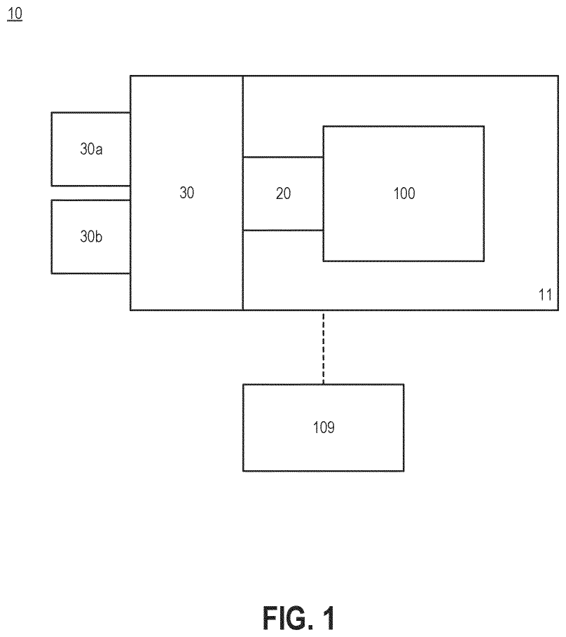

Reference is now made to FIG. 1, which illustrates an exemplary electron beam inspection (EBI) system 10 that may be used for detection, consistent with embodiments of the present disclosure. EBI system 10 may include a scanning electron microscope (SEM) and may be used for imaging. As shown in FIG. 1, EBI system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a wafer under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures of the wafer, and thus may indicate whether the wafer includes defects.

The intensity of the secondary particle beams may be determined using a detector. The secondary particle beams may form beam spots on a surface of the detector. The detector may generate electrical signals (e.g., a current, charge, voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures under inspection. The reconstructed images may be used to reveal various features of the internal or external structures of the wafer and may be used to reveal defects that may exist in the wafer.

Some embodiments of the disclosure may relate to the design and operation of a multi-beam charged-particle apparatus that may utilize a plurality of charged-particle beams. One of the realizations of such apparatus is a high-resolution imaging system using the principles of a multi-beam SEM. In particular, a multi-beam SEM may be implemented as a wafer inspection tool and applied for imaging electrical-circuit patterns fabricated on semiconductor wafers. Conventional single-beam SEMs are widely adopted in the semiconductor industry as a wafer inspection tool. A primary advantage of SEMs may be their high resolution and sensitivity to surface charge distribution that makes them sensitive to a wide variety of fabrication defects. However, for surface imaging, these tools utilize a single electron beam scanned across an inspected area, and therefore they greatly suffer from a low image acquisition speed. In a multi-beam SEM, to increase measurement speed, an inspected area may be split into a plurality of sub-regions, all scanned simultaneously by a plurality of focused electron beams. Such systems may be useful as high-throughput and high-resolution inspection tools for the wafer and mask inspection in the semiconductor industry.

In the semiconductor industry, pattern analysis of semiconductor wafers, defect inspection, critical dimension measurements, and process control may be important in the development of any fabrication process of microchips. Even for established processes, the defects associated with different lithography steps on a semiconductor wafer may present challenges for high-volume manufacturing. Therefore, process control based and continuous monitoring of numbers and types of defects may be important.

Wafer inspection systems may help manufacturers to detect defects that occur during the manufacturing process, therefore allowing them to monitor and control the process and increase the yield of integrated circuit (IC) chips.

In comparative systems, optical inspection systems were common industrial tools to perform wafer defect inspection, critical dimension measurements, and overall silicon-wafer metrology. However, the evolution of the semiconductor industry over the last few decades and the tremendous growth of the packing density of individual components in microchips lead to a pronounced decrease in the component size. This is evident from the node size decrease from generation to generation of microchips during the last few decades. For the latest generation of microchips, the node size has reached the scale of just a few nanometers.

For the inspection of low nanometer-size nodes, optical inspection systems have fundamental limitations in imaging resolution and defect sensitivity inherited from optics. The resolution of the systems may be limited by the relatively large wavelength of light compared to the node size. The sensitivity may be limited by the low scattering cross-section of the objects with subwavelength dimensions, that limits the intensity of the backscattered light.

These limitations reduce the sensitivity and the throughput of optical inspection tools, making them less-and-less applicable for wafer analysis. This led to the wide adoption of inspection tools based on the principles of electron optics. These tools employing the principles of scanning electron microscopes offer high imaging resolution and sensitivity to the local charge distribution of a semiconductor wafer, which may be important for defect detection.

Scanning electron microscopes may make use of beams of accelerated electrons focused down to a few nanometers for imaging the sample surface. The high energy electrons impinging on the surface interact with the surface atoms creating probe spots emitting secondary and backscattered electrons. The image of the surface and the local surface composition may be obtained by collecting and analyzing these secondary and backscattered electrons. In particular, the signal intensity of the secondary (or backscattered) electrons recorded versus position of the primary electron beam may be used for obtaining an image of the inspected surface. Such allows applying SEM for visualizing the fine details of the semiconductor circuit structures fabricated on wafers. The sensitivity of the obtained image to the charge distribution on the wafer surface may allow probing of the local charging of the surface. SEMs may be sensitive to defects in the fabricated semiconductor structures.

A conventional single-beam SEM may include two main sections: (i) a primary electron column; and (ii) a secondary electron column (or simply a detector for secondary electrons). Primary and secondary columns are named corresponding to the primary and secondary electrons. Primary electrons may include those originating from the SEM's electron source, transported to, and impinging on the sample surface (e.g., wafer). Secondary electrons may include: (i) low energy secondary electrons emitted from the wafer surface (having Lambert's law electron energy distribution); (ii) backscattered electrons (scattered elastically or inelastically); and (iii) high energy secondary electrons.

The primary electron column typically includes the following main components: an electron gun (the source of primary electrons), a primary imaging system (e.g., a primary electron projection imaging system) with aberration correction components, and a primary electron beam scanning unit. In the electron gun, the primary electrons are generated by emission from a cathode tip; then, they are accelerated to the energies necessary for transporting them through the electron-optical system of the SEM. The primary electron projection imaging system transports the primary electrons from the source to the wafer. The primary electron projection imaging system performs a focusing of the electron beam on the sample surface and adjusts the final kinetic energy before impinging the electrons on the sample surface. The electron-beam scanning deflection unit scans the beam of the primary electrons across an inspected area.

The secondary column collects secondary electrons generated at the sample surface and transports them to the detector. The secondary column may be simple, having only the detector located close to the sample surface. Or, it may be more complex, having components such as an anti-scanning deflection unit, a projection imaging system for the secondary electrons with aberration correction components, and a detector.

A secondary imaging system (e.g., a secondary electron projection imaging system) may project the secondary electrons originating from the sample surface's probe spots onto the detector. The secondary imaging system may be designed to keep the image's position and focus on the detector independent of the system's imaging parameters (e.g., landing energy). The secondary anti-scanning deflection unit may be configured to eliminate the image displacement on the detector due to the moving position of the probe spot (origin position of the secondary electrons).

In the semiconductor industry, the success of inspection and metrology tools employed on the principles of scanning electron microscopy may predominantly be determined by the short wavelength and high scattering cross-section of the accelerated electrons with kinetic energies of 100 eV-100 keV. The short wavelength may help to achieve a high resolution of obtained images, while the high scattering cross-section gives a high intensity of the detected signal and, therefore, a good signal-to-noise ratio (SNR).

Meanwhile, some tools may suffer from low measurement speed. For example, to obtain a surface image, an electron beam may scan across all points of an inspected area. Scanning a single beam focused to a few nanometers spot size across the wafer (e.g., a 30 cm diameter wafer with a surface area of several square centimeters) or even only relatively small preselected areas may be extremely time consuming Thus, a single-beam system may face difficulties to provide the necessary throughput required by the semiconductor fabs for routine in-line wafer inspection.

Higher throughput of inspection tools employing principles of scanning electron microscopes may be achieved by utilizing a plurality of electron beams in parallel to image multiple segments of the inspected area simultaneously. Secondary electron microscopes using multiple electron beams in parallel for imaging semiconductor structures may be referred to as multi-beam SEMs and are of great interest to the semiconductor industry. Examples of such multi-beam SEMs may be found in U.S. Pat. Nos. 9,691,588 and 10,141,160, which are herein incorporated by reference in their entireties.

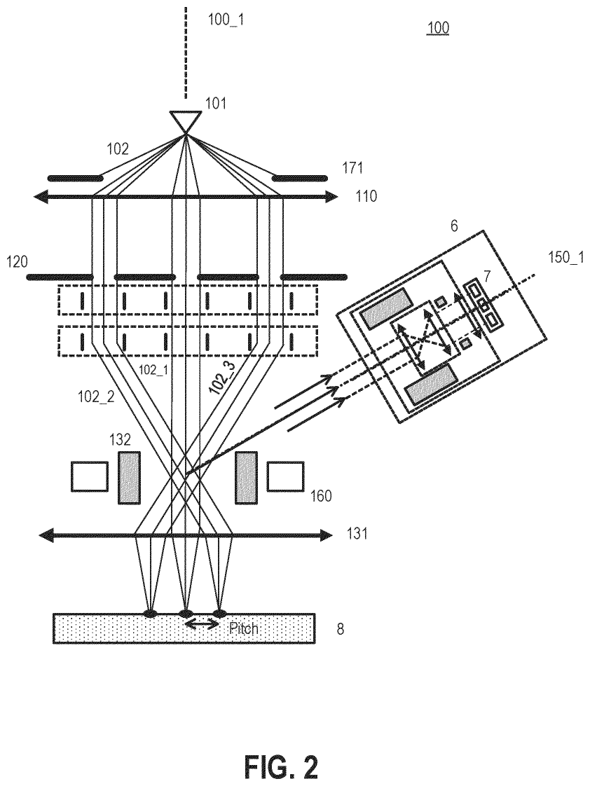

Reference is now made to FIG. 2, which illustrates a multi-beam apparatus, consistent with embodiments of the present disclosure. An electron-optical design of a multi-beam SEM may comprise two main sections: a primary electron column; and a secondary electron column. Electron beam tool 100 may be an example of a charged particle beam apparatus that may be a part of EBI system 10, as discussed above with respect to FIG. 1.

The primary column may include electron-optical components related to the generation of primary electrons, means for forming a plurality of primary electron beamlets, means for transporting primary electron beamlets to a sample surface, and a scanning deflection unit that may be used to scan primary beamlets across an inspected area. The electron source of a multi-beam SEM may be different compared to a conventional single-beam electron source. For example, a multi-beam SEM may be configured to generate a plurality (e.g., an array) of electron beamlets. This may be achieved by supplementing a conventional electron gun with a conversion unit, creating a plurality of virtual electron sources. Examples of a multi-beam system generating a plurality of beamlets are discussed in U.S. Pat. No. 10,141,160.

As shown in FIG. 2, electron beam tool 100 may include an electron source 101, a main aperture plate 171, a condenser lens 110, and a conversion unit 120. Electron source 101, main aperture plate 171, condenser lens 110, and conversion unit 120 may be included in the primary electron column. Electron source 101 may be configured to generate a primary electron beam 102 along a primary optical axis 100_1. Conversion unit 120 may include MEMS (micro electro mechanical systems) structures. For example, conversion unit 120 may include a beam limit aperture, a micro deflector array, and a micro lens array. Electron source 101 may generate primary electron beam 102 that passes through condenser lens 110. Peripheral electrons of primary electron beam 102 may be cut off using main aperture plate 171.

As shown in FIG. 2, a plurality of beamlets 102_1, 102_2, and 102_3 may be generated and may be directed toward a sample 8. Created by the electron gun and conversion unit, an array of nearly parallel electron beamlets may be transported to a surface 7 of sample 8 by one single-column primary projection imaging system. Each beamlet may be focused on a corresponding sub-region of the inspected area. A plurality of the primary electron beamlets hitting the sample surface may create a plurality of probe spots emitting secondary electrons. One common scanning deflection unit performs scanning of the plurality of the beamlets across the sub-regions of the investigated area. For example, electron beam tool 100 may include a beam separator and scanning system. A beam separator may include a Wein filter. As shown in FIG. 2, a beam separator 160 may be provided. A scanning unit (e.g., an electrostatic deflector) may be configured to deflect beamlets to enable scanning. As shown in FIG. 2, scanning deflection unit 132 may be provided. Beam separator 160 and scanning deflection unit 132 may be aligned with primary optical axis 100_1. Scanning deflection unit 132 may deflect beamlets 102_1, 102_2, and 102_3 together so that an array of beam spots scans across surface 7 of sample 8. Beam spots formed by beamlets 102_1, 102_2, and 102_3 may be configured to have a pitch P that may be maintained while scanning is performed.

A single secondary column may be provided and may be configured to collect particles of the plurality of the secondary electron beamlets originating from the plurality of the probe spots within the inspected area's sub-regions and transport them to the detector plane. The secondary column may comprise the objective lens, the beam separator, a secondary electron projection imaging system with an anti-scanning deflection unit, and the detector. There may be overlap between the primary column and secondary column. Some components of electron beam tool 100 may be included in both the primary column and the secondary column. For example, objective lens 131, beam separator 160, and scanning deflection unit 132 may be included in both the primary column and the secondary column.

Although some components such as beam separator 160 may not be involved in a scanning process, electrons may nevertheless travel through them. For example, in some embodiments, a Wien filter plays the role of a beam separator. The Wien filter may transmit primary electrons traveling toward the wafer without affecting their trajectories. This may be achieved by balancing electrostatic force vs. magnetic force (e.g., Lorentz force) acting on the traveling electrons. Both fields are oriented perpendicular to the primary optical axis. On the way back from the wafer to the detector, Lorentz force will change sign, since it may depend on the direction of the motion of electrons, while the electrostatic force will act in the same direction. Both forces will act on the electrons in the same direction (orthogonally to the primary optical axis). As a result, they will deflect the secondary electrons towards the detector (e.g., along the secondary optical axis). The Wien filter may be held under static excitation during scanning.

Scanning may be performed by electrostatic deflectors (e.g., a scanning unit). In some embodiments, an electrostatic deflector may include two metallic plates with a voltage applied between the plates to create an electric field deflecting the electrons in the direction perpendicular to the primary optical axis. Multiple pairs of metallic plates may be provided.

As shown in FIG. 2, there may be provided a secondary imaging system 6 and a detector 7. Secondary imaging system 6 may be an example of a projection imaging system. Secondary imaging system 6 and detector 7 may be aligned with a secondary optical axis 150_1. A secondary column may include objective lens 131, beam separator 160, and scanning deflection unit 132, secondary imaging system 6, and detector 7.

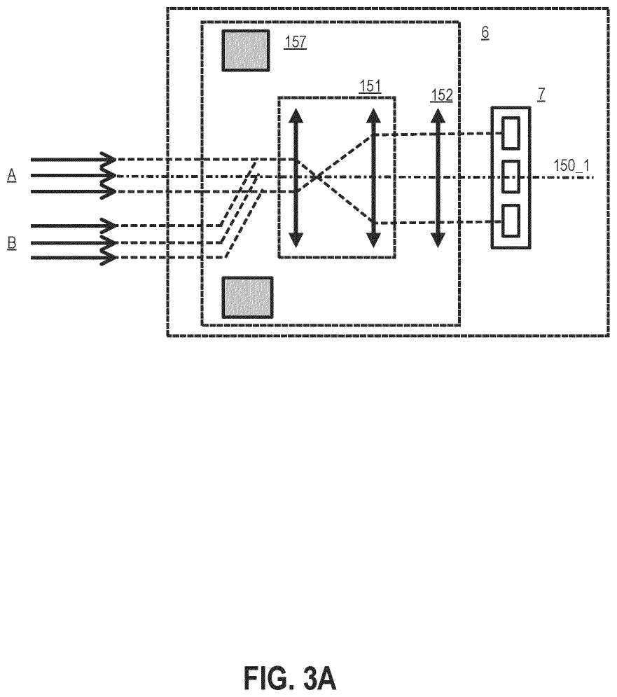

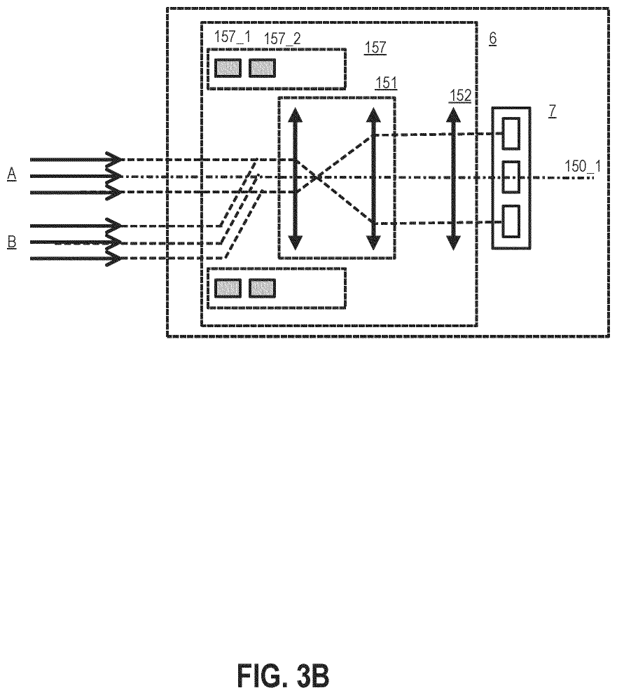

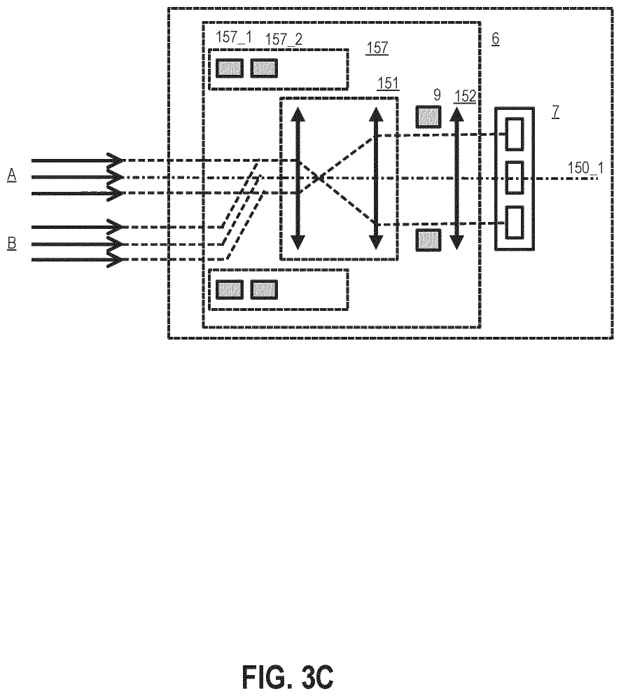

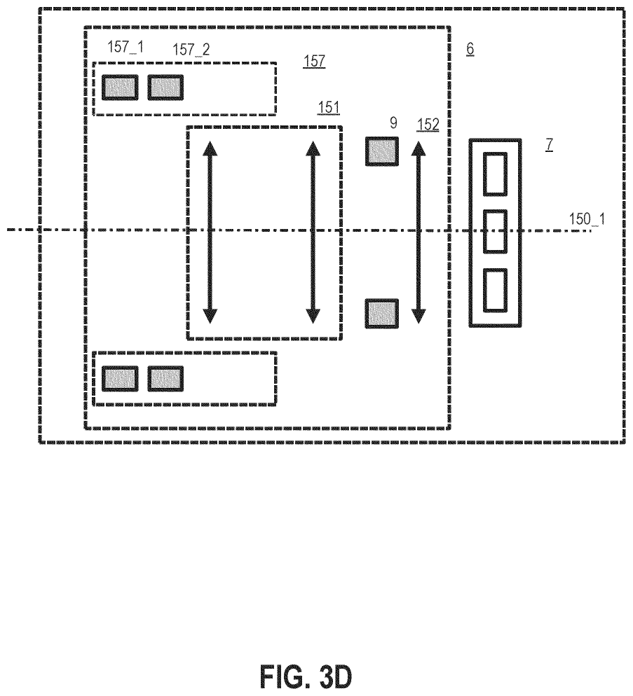

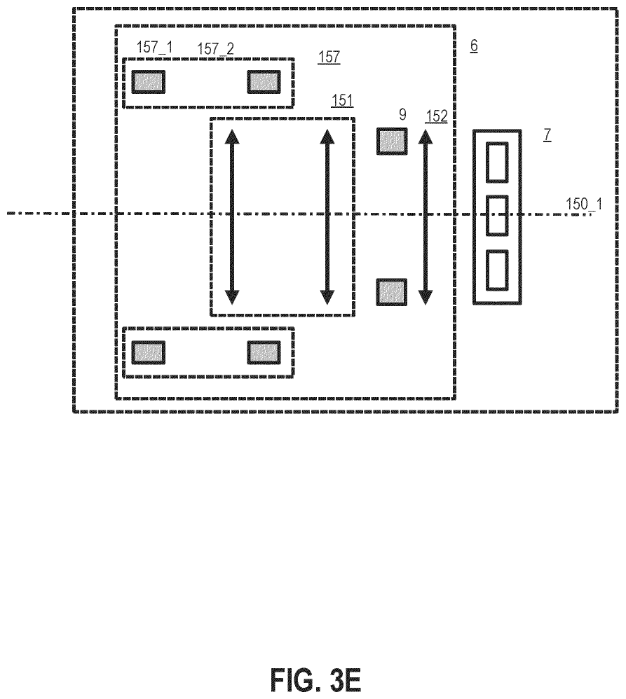

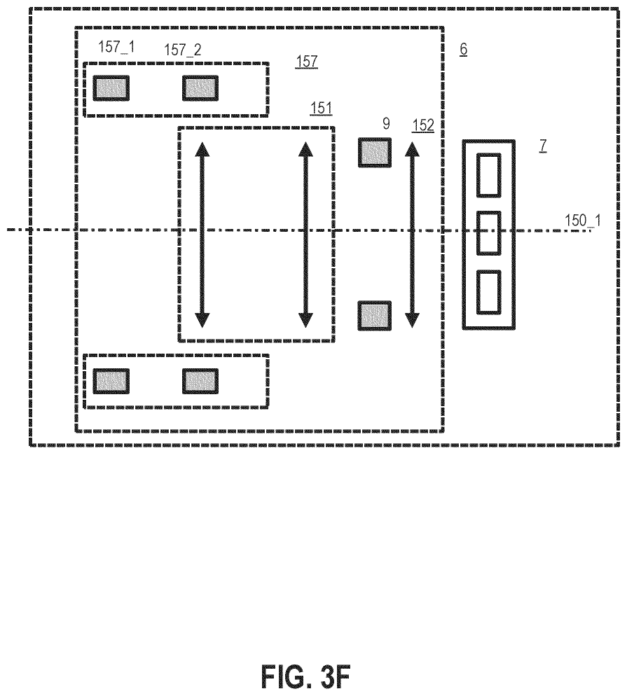

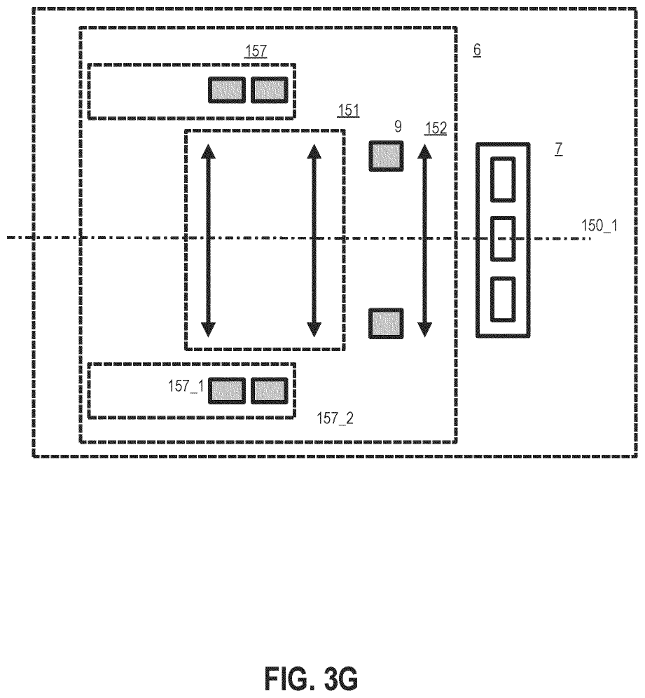

FIG. 3A shows an example of an enlargement of portions of a secondary column, consistent with embodiments of the present disclosure. Secondary imaging system 6 may include an anti-scanning deflection unit 157, a zoom lens 151, and a projection lens 152. Anti-scanning deflection unit 157 may include a deflector configured to deflect secondary electrons. Zoom lens 151 may include a plurality of electrostatic lenses. Projection lens 152 may include an electrostatic lens or a magnetic lens.

With reference to FIG. 2, objective lens 131 may collect the secondary electrons emitted from probe spots and may form beamlets of secondary electrons (“secondary electron beamlets”). Beam separator 160 may deflect the secondary electron beamlets toward secondary imaging system 6. Secondary imaging system 6 may be used to project the secondary electrons onto detector 7 and to keep the focus, size, and rotation of the image on detector 7 nearly constant and independent of the SEM imaging conditions.

As shown in FIG. 3A, secondary imaging system 6 may include components that influence beams travelling therethrough. Components in secondary imaging system 6 may influence beamlets together. For example, common for all beamlets entering secondary imaging system 6, anti-scanning deflection unit 157 may shift the incoming array of secondary-electron beamlets with respect to secondary optical axis 150_1. Anti-scanning deflection unit 157 may be configured to minimize the image displacement on detector 7. Image displacement on detector 7 may originate from the motion of probe spots across the inspected area on surface 7 of sample 8. Anti-scanning deflection unit 157 may influence beams in step with an electron deflection scanning system of the primary electron beamlets. For example, anti-scanning deflection unit 157 may influences beamlets in step with scanning deflection unit 132. Detector 7 may detect electrons coming as a plurality of the beamlets. Detector 7 may be assembled from individual sensors, or may be implemented as one detector with a plurality of sensitive elements (e.g., detector segments or groups of sensitive elements, such as a group of small pixels). Each secondary beamlet may be configured to be projected onto the corresponding detector or the detector segment.

FIG. 3B shows a further example of an arrangement of a secondary imaging system, consistent with embodiments of the present disclosure. As shown in FIG. 3B, a plurality of deflectors may be provided for an anti-scanning secondary-electron deflection unit. For example, there may be provided at least two deflectors 157_1 and 157_2. Deflector 157_1 may be configured to deflect beamlets toward secondary optical axis 150_1, and deflector 157_2 may be configured to deflect beamlets back so that they have a trajectory parallel to secondary optical axis 150_1.

In some embodiments, a secondary-electron projection imaging system may comprise a combined zoom lens (including at least two lenses), an anti-rotation lens, and aberration compensation electron-optical elements (e.g., stigmators). Each of the lenses may be an electrostatic lens, a magnetic lens, or an electrostatic-magnetic compound lens. In addition, each lens may be implemented as a single lens or as an ensemble of lenses (e.g., some lenses performing coarse and some performing fine focusing). The same may be true for aberration-compensation electron-optical elements.

In a comparative embodiment, all components of the secondary projection imaging system may be chosen to provide the best average performance for a plurality of the beamlets, and excitations of the components are fixed to specific values during the scanning.

The secondary-electron projection imaging system may be configured to keep constant the magnification, focusing, and rotation of the image on the detector. Such parameters (magnification, focusing, image rotation) should be independent of the imaging parameters of the multi-beam system (e.g., landing energy, parameters controlling secondary electrons emission modes, etc.).

The plurality of the secondary-electron beamlets originating from the plurality of probe spots may be transported and focused on the detector. The detector may perform detection of the electrons utilizing established one-to-one correspondence between the particular sub-region of the inspected area with one of the detection cells.

Performance of the secondary column in a multi-beam charged particle apparatus may be determined by two main parameters: collection efficiency and cross-talk. The collection efficiency of a single detector cell may be defined as a fraction of the secondary electrons emitted from a corresponding probe spot within one of the sub-regions of the inspected area and detected by the corresponding detection element. Collection efficiency may be initially defined for each detection element. In some embodiments, for characterization of the whole detector, the average value for the collection efficiency of all detection elements may be derived. In some embodiments, collection efficiency may be supplemented with numbers characterizing the spread of values between elements, such as minimum and maximum values across all elements of the detector.

Cross-talk may be defined as a fraction of the secondary electrons detected by an individual detector cell originating not from the corresponding sub-region of the scanned area but from neighboring sub-regions. Similar to the collection efficiency, the average, minimum, and maximum values across all elements of the detector may be calculated for characterization of the entire detector.

High collection efficiency and low cross-talk may be significant design parameters for achieving high resolution and high throughput for a multi-beam charged-particle apparatus to be utilized as defect inspection tools at semiconductor manufacturing fabs.

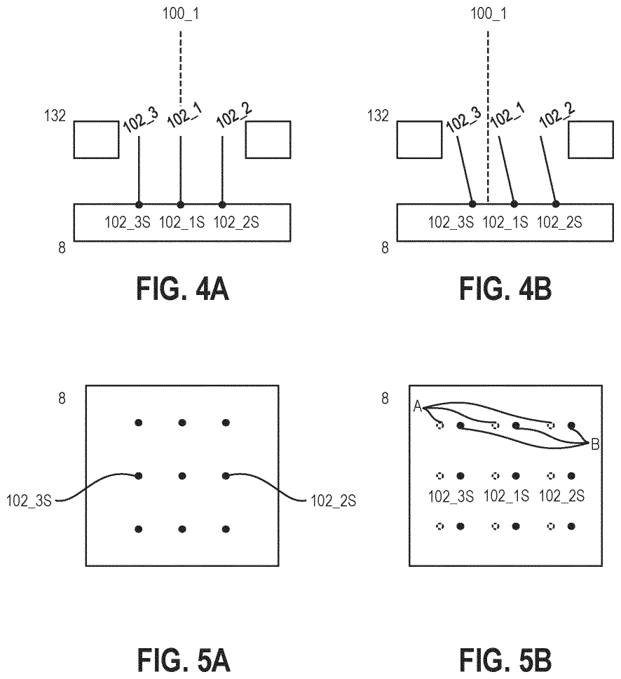

Reference will now be made to FIG. 4A, FIG. 4B, FIG. 5A, and FIG. 5B, which illustrate scanning of primary electron beams, consistent with embodiments of the present disclosure. FIG. 4A and FIG. 4B show a side view of a portion of a primary electron column. Beamlets 102_1, 102_2, and 102_3 may be formed in the primary electron column and may travel parallel to primary optical axis 100_1. Beamlets 102_1, 102_2, and 102_3 may strike sample 8 and form beam spots 102_1S, 102_2S, and 102_3S. Scanning deflection unit 132 may be configured to deflect beams traveling therethrough. As shown in FIG. 4B, scanning deflection unit 132 may deflect beamlets 102_1, 102_2, and 102_3 so that beam spots 102_1S, 102_2S, and 102_35 move across sample 8. FIG. 5A and FIG. 5B show corresponding top views of sample 8.

In the scanning operation mode of a multi-beam SEM, the primary deflection scanning unit constantly moves the array of the primary beamlets across the inspected area. For example, scanning deflection unit 132 may deflect beamlets 102_1, 102_2, and 102_3 so that beam spots 102_1S, 102_2S, and 102_3S move from position A to position B, as shown in FIG. 5B. Beamlets may be deflected together so that beam spots on the sample surface move as a unit. Secondary electrons may be generated at each position that corresponding probe spots are formed at on the surface of the sample. The origin positions of the secondary electron beamlets during scanning may change constantly in operation, and the paths of the secondary electron beamlets through the electron-optical system also changes. However, in a comparative multi-beam SEM, the excitations of electron-optical elements of the secondary projection imaging system (e.g., lenses, stigmators, and other aberration compensation elements) are optimized only for the undeflected position of the beamlets and kept the same during scanning.

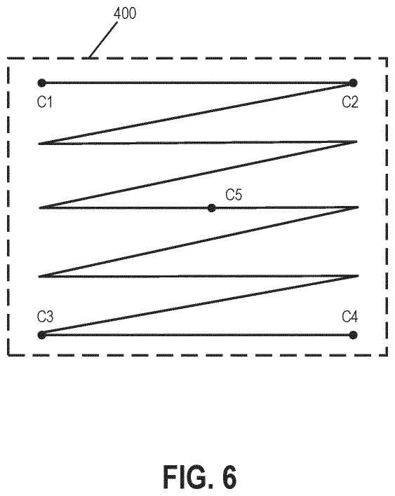

FIG. 6 illustrates a scan area and scan path, consistent with embodiments of the present disclosure. As shown in FIG. 6, a scan area 400 may be provided on a surface of a sample. Scan area 400 may correspond to a FOV of a charged particle beam apparatus. The scan area may be within the FOV of the charged particle beam apparatus. During a scanning operation, a primary charged particle beam may scan in a raster pattern to cover scan area 400. In some embodiments, multiple beamlets may be used, and the scan path of each beamlet may correspond to that shown in FIG. 6, or the scan path of the array of beamlets may correspond to that shown in FIG. 6. The scan path may begin at a point C1 and proceed in a sawtooth pattern, or some other pattern. Points C1, C2, C3, and C4 may be the corners of scan area 400. Points C1, C2, C3, and C4 may be the fully deflected positions of the beam. Point C5 may be at the center of scan area 400. Point C5 may be an undeflected position of the beam. A secondary imaging system may be optimized for conditions of an undeflected beam, for example, when the primary beam is at point C5. When the primary beam is at points C1, C2, C3, or C4, secondary charged particles may be generated from beam spots at these points and travel to the secondary imaging system therefrom.

As shown in FIG. 5B and FIGS. 3A-3G, secondary beamlets originating from position B may be offset relative to secondary optical axis 150_1 as they enter secondary imaging system 6. Anti-scanning deflection unit 157 of secondary imaging system 6 may be configured to compensate for such offset and may redirect beamlets to be aligned with optical axis 150_1, so that trajectories of beamlets may be similar to beamlets originating from position A (e.g., undeflected beamlets). Anti-scanning deflection unit 157 may cancel the shift of the secondary beamlet array that occurs due to scanning. It will be understood that anti-scanning deflection unit 157 may not need to deflect undeflected beamlets (e.g., those originating from position A).

However, even when offset is corrected (e.g., by shifting deflected beamlets), some properties of beamlets may not be the same as undeflected beamlets. For example, secondary beamlets originating from deflected positions within scan area 400 (e.g., at points C1, C2, C3, or C4) may have optical paths different from that of undeflected beamlets (e.g., a secondary beamlet originating from point C5). Corresponding trajectories of the secondary electrons included in the secondary beamlets may have different lengths and go through different points within the electron-optical components (e.g., lenses, Wien filter, etc.) of the secondary projection imaging system. Secondary beamlets may be affected differently by the electron-optical components and experience different aberrations. If excitations of components of the secondary imaging system are kept the same during scanning, these effects are not compensated by the lenses and stigmators, therefore the image created by the secondary imaging system may become defocused (e.g., the beam spot may be broadened) and the image may suffer from directional smearing effects (e.g., astigmatism). Degraded image quality on the detector may result in decreasing collection efficiency and worsening cross-talk of the detector cells for full FOV (Field of View) below theoretically possible values.

As an example, in a comparative embodiment, a secondary imaging system may not be optimally configured to handle secondary charged particles originating from points C1, C2, C3, or C4, as shown in FIG. 6, and there may be deviation in image quality as compared to a situation where secondary charged particles originate from point C5. The secondary imaging system may be configured to apply certain excitation conditions to components therein to achieve focusing of beamlets onto respective regions of a detector.

In the comparative embodiment, deviation from optimal excitation conditions for the electron-optical elements of the secondary projection imaging systems may be considered to be small and remains uncompensated. However, at certain imaging conditions, deterioration of the image quality of the imaged probe spots may become very pronounced. In such cases, re-optimization of the secondary projection imaging system at each step of the scan may improve the image quality on the detector.

In some embodiments of the disclosure, an anti-scanning operation mode may be provided for a secondary imaging system of a multi-beam apparatus. In some embodiments, an anti-scanning operation mode may be applied to a variety of embodiments of a multi-beam apparatus design and a secondary imaging system, for example those discussed in U.S. Pat. Nos. 9,691,588 and 10,141,160. Compared to a standard scan mode, anti-scanning operation mode may enhance collection efficiency and reduce cross-talk in a secondary imaging system for all points of an FOV.

In a comparative embodiment, a standard scan sequence may include:
1. A primary scanning deflection unit deflects primary beamlets that move probe spots across an inspected area.
2. A secondary anti-scanning deflection unit acts to cancel the shift of a secondary electron beamlet array with respect to the secondary imaging system's optical axis on the detector.
3. The secondary imaging system is kept fixed (e.g., having fixed excitation values of electron-optical components in the secondary imaging system) in a state corresponding to the optimization performed for the undeflected position of the primary beamlets.

In some embodiments, a modified scan sequence may be used that includes an anti-scanning operation mode for the secondary imaging system. The modified scan sequence may be similar to that noted above for a standard scan sequence except that in step 3, instead of fixing the secondary imaging system's excitations, such excitations may be synchronously updated in step with the primary scanning deflection unit performing scanning, or the anti-scanning deflection unit performing anti-scanning. Synchronously with the primary scanning deflection unit or the anti-scanning deflection unit, other components of the secondary imaging system may be adjusted. Adjusting excitation in the anti-scanning operation mode may compensate for changes produced by the scan in initial imaging conditions for the secondary imaging system. The anti-scanning operation mode may perform an anti-scanning function for the secondary imaging system as a whole. Anti-scanning operation mode may enhance focusing and compensation of aberrations in the secondary imaging system at any point of FOV and may minimize deterioration of probe spot images on the detector.

In some embodiments, all electron-optical components of a secondary projection imaging system may be updated synchronously with primary scanning deflection units, acting together as a single optical system to cancel effects on the image produced by the scanning of the primary-electron beamlets. A method of operating a secondary imaging system may include using an anti-scanning mode of the secondary imaging system. A charged particle beam system may include an anti-scanning secondary imaging system.

A range of changing excitation values of the electron-optical components of the secondary imaging system may be determined for all probe spot positions within the FOV or scan area on a sample by theoretical modelling. In some embodiments, the range of changing excitation values may be determined experimentally. In some embodiments, interpolation may be used. For example, the number of computations may be reduced by finding excitation values for a subset of the positions (e.g., center and corners) and use interpolation to determine the intermediate values.

Reference is now made to FIG. 3C, which illustrates a further arrangement showing an enlargement of portions of a secondary column, consistent with embodiments of the present disclosure. Like the example of FIG. 3A or FIG. 3B, as shown in FIG. 3C, secondary imaging system 6 may include an anti-scanning deflection unit 157, a zoom lens 151, and a projection lens 152. However, secondary imaging system 6 may also include a stigmator 9. Stigmator 9 may be configured to compensate for astigmatism aberrations of the plurality of secondary electron beams entering secondary imaging system 6 due to beam separator 160. Some components may be configured to compensate for aberrations due to objective lens 131. Furthermore, projection lens 152 may be configured as an anti-rotation lens. Projection lens 152 may be configured to compensate for rotation effects induced by other components of secondary imaging system 6. Components of secondary imaging system 6 may be configured to keep a corresponding relationship between images of the plurality of probe spots formed by the plurality of primary beamlets and the plurality of detection elements in detector 7. The detection elements may include individual or groups of sensing elements, or may include different sub-regions of detector 7. By the corresponding relationship, each detection element may generate an image signal of one corresponding scanned region.

In some embodiments, secondary imaging system 6 may further comprise an alignment deflector to compensate for deviation of the corresponding relationship due to manufacturing or assembly errors of components of the secondary column, including, e.g., detector 7.

In some embodiments, an arrangement of components in secondary imaging system 6 may be changed. For example, anti-scanning deflection unit 157 may be between beam separator 160 (see FIG. 2) and zoom lens 151. Anti-scanning deflection unit 157 may be the leading component in secondary imaging system 6. In some embodiments, anti-scanning deflection unit 157 may be between zoom lens 151 and detector 7. In some embodiments, anti-scanning deflection unit 157 may be between individual lenses of zoom lens 151.

Further examples of different arrangement of components in secondary imaging system 6 are shown in FIGS. 3D-3G. For example, FIG. 3D shows an arrangement where all anti-scanning deflectors are located before (e.g., upstream from) zoom lens 151. In some embodiments, the arrangement of FIG. 3D may be configured to enable optimal scenarios for performance of secondary imaging system 6. FIG. 3E shows an arrangement that may be useful due to space constraints before zoom lens 151. As shown in FIG. 3E, at least one anti-scanning deflector 157_1 may be located before zoom lens 151, and at least one anti-scanning deflector 157_2 may be located after zoom lens 151. FIG. 3F shows an arrangement that may be useful due to further space constraints. As shown in FIG. 3F, at least one anti-scanning deflector 157_2 may overlap with a first zoom lens of zoom lens 151. FIG. 3G shows an arrangement that may be useful due to further space constraints. As shown in FIG. 3F, all anti-scanning deflectors may be located after a first zoom lens of zoom lens 151.

In operation, secondary particles generated from beam spots on a sample may be incident into secondary imaging system 6 from position A, as shown in FIG. 5B and FIGS. 3A-3G. Position A may correspond to an undeflected position of an array of primary beamlets on the sample, and secondary beamlets incident into secondary imaging system 6 may be undeflected. Position B may correspond to a deflected position of the array of primary beamlets on the sample, and secondary beamlets incident into secondary imaging system 6 may be deflected. Anti-scanning deflection unit 157 may deflect beamlets from position B so as to correct for offset. Beamlets may be shifted back such that they are aligned with secondary optical axis 150_1. Anti-scanning deflection unit 157 may perform anti-scanning synchronously with scanning deflection unit 132 (see FIG. 2). Together with scanning of primary beamlets, secondary beamlets may be anti-scanned. Furthermore, other components may be operated in an anti-scanning mode. Other components in secondary imaging system 6 may be operated with an excitation that is adjusted synchronously with anti-scanning deflection unit 157 or scanning deflection unit 132.

Excitation of components of secondary imaging system 6 may include adjusting an electrical signal applied to a lens, for example. The excitation may include a voltage or current of a driver. For example, a voltage applied to an electrostatic lens of zoom lens 151 may be adjusted. Adjustment of excitation of an electrostatic lens may include changing voltages applied to electrodes of the electrostatic lens. A compound lens may include electrodes to which voltage may be adjusted. Adjusting of excitation may be based on a deflection setting of a scanning deflector or an anti-scanning deflector. In some embodiments, a deflection setting of the scanning deflector may correspond to a deflection setting of the anti-scanning deflector. A component of secondary imaging system 6 may be adjusted based on a deflection setting of anti-scanning deflection unit 157. For example, when anti-scanning deflection unit 157 deflects secondary beamlets from position B to align with secondary optical axis 150_1 (e.g., similar to secondary beamlets from position A), an excitation of zoom lens 151 may be adjusted. A degree of adjustment of the excitation may be based on a relationship between an amount of deflection and an effect on image quality (e.g., an expect amount of aberration caused by the deflection). In some embodiments, the degree of adjustment of the excitation may be proportional to the amount of deflection.

In some embodiments, adjustment of excitation of components of secondary imaging system 6 may be done one-by-one. For example, excitation applied to zoom lens 151, projection lens 152, and stigmator 9 may be adjusted one-by-one. In some embodiments, excitation applied to all components of secondary imaging system 6 may be adjusted together. For example, together with operation of anti-scanning deflection unit 157, excitation applied to zoom lens 151, projection lens 152, and stigmator 9 may be adjusted.

In some embodiments, for example when anti-scanning deflection unit 157 is upstream from other components in secondary imaging system 6 to be adjusted, excitation applied to the other components may be adjusted together. In some embodiments, for example when other components are upstream from anti-scanning deflection unit 157, such components may be adjusted differently from components downstream from anti-scanning deflection unit 157. For example, lenses upstream of anti-scanning deflection unit 157 may be adjusted to compensate for aberration variation that may be due to beamlets being deflected. Beamlets entering such lenses may not have had their offset corrected for by anti-scanning deflection unit 157, and the beamlets may experience additional distortion. Such distortion may be compensated for by adjusting excitation of the lens in step with scanning of the primary beamlets. For example, a lens provided as a leading component of secondary imaging system 6 may be configured to compensate for aberration that is due to deflected beamlets passing through objective lens 131 and beam separator 160 before reaching secondary imaging system 6.

Although illustrated in FIGS. 3A-3G as being parallel, in some embodiments, deflected secondary beamlets (e.g., from position B) may be incident into secondary imaging system 6 at angles that are different from that of undeflected beamlets (e.g., from position A). For example, beamlets from position B may enter secondary imaging system inclined relative to secondary optical axis 150_1. Anti-scanning deflection unit 157 may shift beamlets such that their offset is cancelled, however, the trajectory of the beamlets may still be inclined relative to secondary optical axis 150_1. In some embodiments, components of secondary imaging system 6 may be configured to correct for inclination angles of incident deflected beamlets. Anti-scanning deflection unit 157 may be configured to cancel not only offset but also inclination angles.

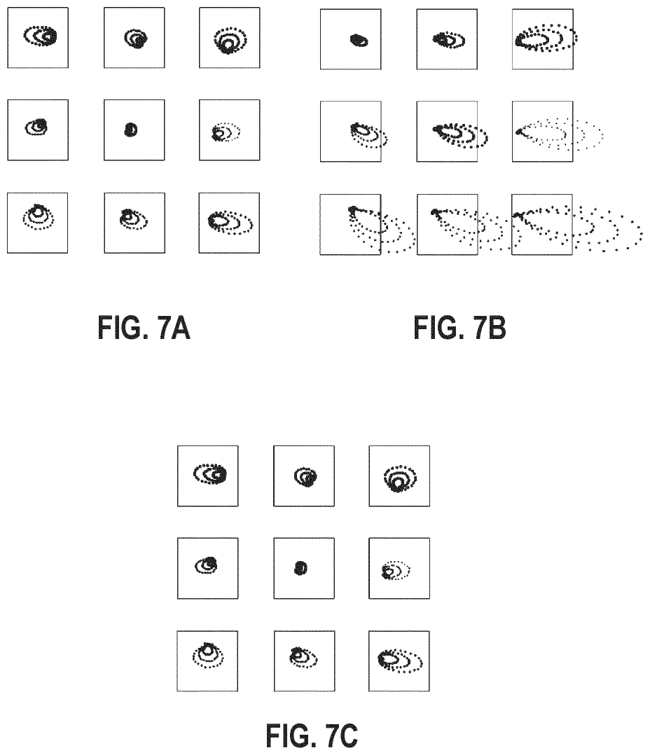

Reference is now made to FIGS. 7A-7C, which illustrate projection of beam spot images on detector cells of a detector, consistent with embodiments of the disclosure. FIGS. 7A-7C may schematically show electron spot distributions created by secondary imaging system 6 on detector 7 via contours. Contours of electron spot distributions may be used to characterize size and shape of the spots. FIG. 7A illustrates spots on the detector that may correspond to undeflected position of probe spots within the FOV of a charged particle beam apparatus. As shown in FIG. 7A, spots on the detector generally have a rounded shape and are well focused. This may be due to excitations of components of the secondary imaging system being fully optimized. FIG. 7B illustrates spots on the detector that may correspond to a case with the primary electron beamlets being deflected to one of the FOV corners. Simultaneously, excitations of components of the secondary imaging system may be kept fixed (e.g., using a standard scan mode). In the case of FIG. 7B, spots are larger and come in strongly distorted shapes as compared to FIG. 7A. Distortion of spots in FIG. 7B may be due to the focusing and compensation of aberrations being kept the same as in the case of FIG. 7A. As shown in FIG. 7B, some spots are larger than individual cells of the detector. This may lead to low collection efficiency and considerable cross-talk.

In some embodiments, anti-scanning mode of a secondary imaging system may be used. For example, secondary imaging system 6 (see FIGS. 3A-3G) may be configured to fully reoptimize excitations of components of secondary imaging system 6 based on deflection of beamlets entering secondary imaging system 6. As shown in FIG. 7C, spots on detector 7 corresponding to deflected beamlets may be similar to those corresponding to the undeflected beamlets (see FIG. 7A). Anti-scanning mode may allow secondary imaging system 6 to achieve better collection-efficiency and less cross-talk values compared to standard operation. This may enable higher resolution and higher speed operation. For example, high-speed and high-resolution measurement may be taken in electron beam inspection processes. For defect inspection systems, higher throughput, sensitivity, and accuracy may be achieved.

Anti-scanning may be performed without the use of a feedback loop. For example, in a comparative embodiment, a monitoring system may be provided that images a beam spot projection pattern on a detector and then makes corrections based on the imaged projection pattern. In some embodiments of the present disclosure, a feedback loop that uses images of beam spots projected on the detector may be omitted. Dynamic adjustment of components of a secondary imaging system (e.g., dynamic focusing) may be achieved without requiring a monitoring system and feedback loop. By omitting a feedback loop, substantially all of the detection signal generated by the beam spots on the detector may be used for signal generation, and SNR may be enhanced. Furthermore, an anti-scanning mode of operation of a secondary imaging system may be applied directly to a charged particle beam apparatus without requiring further addition of hardware, such as a monitoring system.

In some embodiments, secondary imaging systems such as those discussed in U.S. Pat. Nos. 9,691,588 and 10,141,160 may be used. It will be understood that in some embodiments, further variations may be used, such as anti-scanning deflection unit 157 being placed further downstream from zoom lens 151, and different arrangements of lenses (e.g., ensemble lenses).

Furthermore, in some embodiments, shapes of beam spots on a detector may be tuned. There may be provided a method of optimizing electron-beam spots on the detector and optimizing the shape and size of the detector cells in a charged particle beam apparatus (e.g., a multi-beam SEM). In a comparative embodiment, a circular shape of electron beam spots may be targeted to be formed on a detector. However, other shapes may be used to enhance performance of the detector. For example, an elongated shape, such as an elliptical shape of spots on the detector may help to reduce cross-talk and increase collection efficiency. The orientation of the ellipse may be aligned along the diagonals connecting the nearest neighbors of detector cells. Corresponding methods for optimizing the shape and size of detector cells for a pixelated detector for a multi-beam apparatus may also be provided.

Some embodiments may relate to the operation of a multi-beam charged-particle apparatus that utilize a plurality of charged-particle beams. One of the realizations of such apparatus is a high-resolution imaging system using the principles of a multi-beam Scanning Electron Microscope (SEM). In particular, a multi-beam SEM can be implemented as a wafer inspection tool and applied for imaging electrical-circuit patterns fabricated on semiconductor wafers. Conventional single-beam SEMs are widely adopted in the semiconductor industry as a wafer inspection tool. The primary advantage of SEM's is their high resolution and sensitivity to surface charge distribution that makes them sensitive to a wide variety of fabrication defects. However, for surface imaging, these tools utilize a single electron beam scanned across an inspected area, and therefore they greatly suffer from a low image acquisition speed. In a multi-beam SEM to increase the measurement speed, an inspected area is split into a plurality of sub-regions, all scanned simultaneously by the plurality of focused electron beams. Such systems may achieve high-throughput and high-resolution, and may be useful tools for wafer and mask inspection in the semiconductor industry.

In single beam electron systems (e.g., SEMs), electron beams with circular cross-sections may be used. The electron beams may be centered on the optical axis of the system and have rotational symmetry around the optical axis. Unless the shape of the beam is distorted by aberrations or affected by optical elements (e.g., by stigmators or deflectors), the minimum footprint (and therefore the best resolution) on image planes are typically obtained for electron spots of a circular shape. Naturally, the circular shape of the electron spots on the image planes (e.g., sample surface, detector surface) may be used as a targeted shape for optimization of system performance.

In some embodiments, for example, for multi-beam SEMs, a circular shape of the electron spots on the detector may not be the best shape to obtain the system's best achievable performance. Shapes other than a circular shape may be targeted.

A method may be provided of optimization of the electron-beam spots on the detector of a charged particle beam apparatus (e.g., a multi-beam SEM). A parameter of the electron-beam spots may be adjusted. The parameter may include size, shape, or arrangement of the electron-beam spots, for example. An elongated shape of the spots on the detector may be used to minimize cross-talk and maximize collection efficiency values. The orientation of the elongated shapes may be along the diagonals connecting the nearest neighbors of detector cells. The elongated shapes may include ellipses.

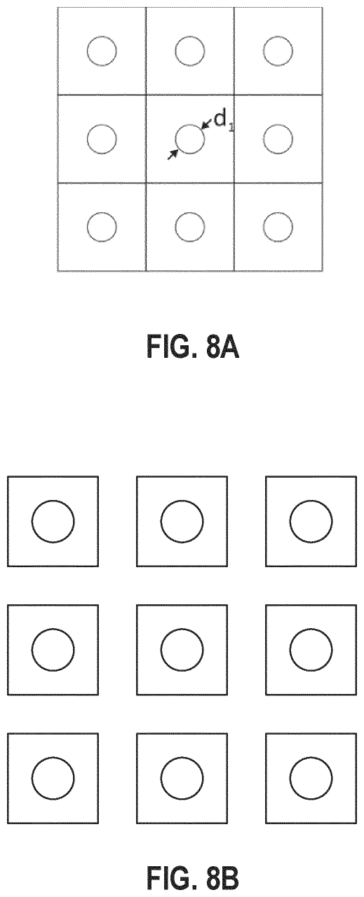

Reference is now made to FIG. 8A and FIG. 8B, which illustrate beam spots of circular shape, consistent with embodiments of the disclosure. In a comparative embodiment, a standard optimization may be represented by FIG. 8A. The standard optimization may include: (i) spots are optimized to have a circular shape, (ii) diameters of the spots (d₁) are minimized FIG. 8A shows such optimization on the detector with individual detector cells arranged side by side (without spacing) in a square lattice. FIG. 8B shows the same standard optimization on the detector with the cells arranged in a square lattice with gaps between the cells. In detectors assembled from individual elements, the “side-by-side” arrangement or the arrangement having gaps between the cells may be determined in the system design. With the appearance of 2D pixelated detectors, the size and the shape of the individual detector cells and spacing between them may be adjusted during the measurements. The choice of these parameters may become a part of the methods for optimizing the system detection performance.

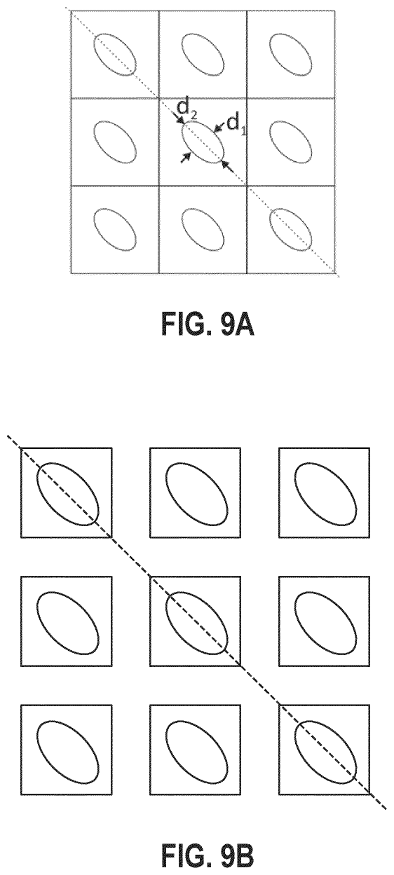

Reference is now made to FIG. 9A and FIG. 9B, which illustrate beam spots of a shape other than circular, consistent with embodiments of the disclosure. In some embodiments, a procedure for optimization may include: (i) spots are optimized to have an elongated (e.g., elliptical) shape with the elongation oriented along the lines connecting the neighboring diagonal elements of the detector, (ii) size of the minor axes (short axis perpendicular to the line) is minimized, while the major axes (long axis) can be somewhat longer. In the case of a regular arrangement of detection elements in a square N×N matrix array, the major axis may be about 1.4 times larger than the minor axis. FIG. 9A shows square detector cells arranged side by side in a square lattice. FIG. 9B shows square detector cells arranged in a standard square lattice with gaps left between the cells.

Using shapes other than a circle, larger spot sizes along the diagonal directions may be justified considering the distances between neighboring elements in the N×N square matrix array. In some embodiments, the distance between adjacent detector cells located diagonally is √2 (square root of 2) times larger than the distance between the neighboring detector cells located horizontally or vertically. Spot size along the diagonal directions may be made larger without increasing the overlap between corresponding spots. Spot size may be increased without increasing cross-talk and without decreasing collection efficiency. Criteria for optimizing the shape of a beam spot may be relaxed in this regard without detrimental effects on cross-talk and collection efficiency, for example.

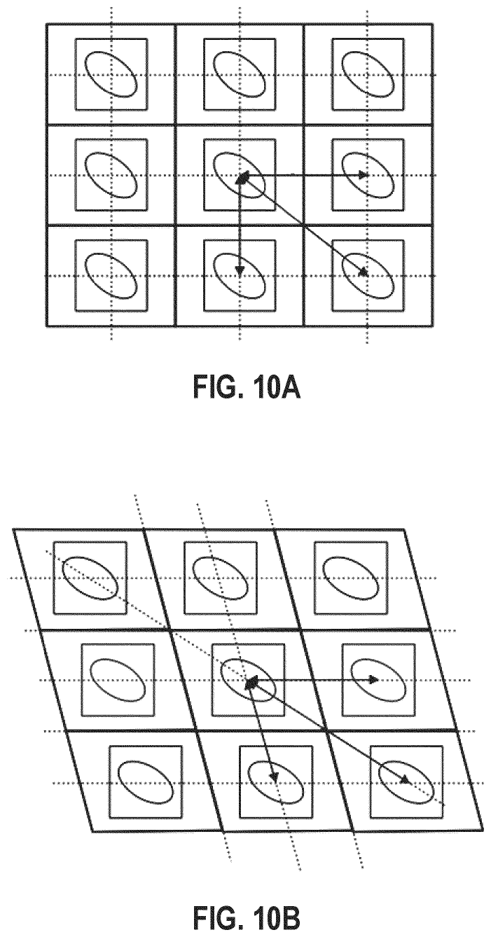

Reference is now made to FIG. 10A and FIG. 10B, which illustrate beam spots of a shape other than circular, and detector cells in an offset pattern, consistent with embodiments of the disclosure. In some embodiments, spots and corresponding detector cells may be arranged in an N×N matrix having a shape close to a rectangle or parallelogram. The detector cells may be arranged in a lattice formation where elements of the lattice have a parallelogram shape. A procedure for optimization may include: (i) spots are optimized to have an elliptical shape with the ellipses oriented along the lines connecting the neighboring diagonal elements of the detector, (ii) size of the minor axes (short axis perpendicular to the line) is minimized, while the major axes (long axis) can be somewhat longer. In this case, the scaling factor for the long axis (oriented along the diagonal line) with respect to the short axis (oriented perpendicular to the diagonal line) may be estimated to be, e.g., √(a\hat{ }2+b\hat{ }2)/c. In some embodiments, scaling factor may be estimated as (½*(a+b))/c. In some embodiments, scaling factor may be estimated as a/c. The cell shape and size may be adjusted to utilize larger cell pitch in different directions and distortions of the cell array, as shown in FIG. 10B. Furthermore, in some embodiments, spots may be optimized to have an elongated shape that is elongated along a line that connects neighboring lattice elements of a detector array. For example, as shown in FIG. 10B, a plurality of detector cells may be arranged in an array such that lattice elements of the array have a parallelogram shape while the detector cells have a rectangular shape. The line connecting neighboring lattice elements may not necessarily align with diagonal lines traced from corners of individual detector cells.

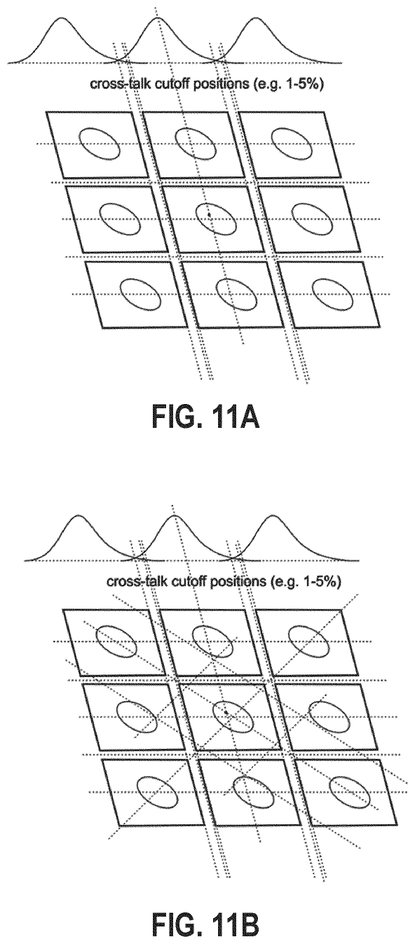

Reference is now made to FIG. 11A and FIG. 11B, which illustrate beam spots that may have asymmetrical distribution, consistent with embodiments of the disclosure. For spots with asymmetrical distribution (e.g., due to comma aberration) with respect to geometrical spot centers, detector cells may be shifted to cover the maximum part of the spots and leaving only minor tails of the spot distributions outside of the cells (see FIG. 11A). Gaps between cells may be provided and left open to minimize cross-talk between the elements. The positioning of the cell boundaries may be determined using the projected intensity distribution of the spot on corresponding axes connecting neighboring detector cells. In some embodiments, the boundary positions may be optimized based on a ratio between collection efficiency and cross-talk. In some embodiments, this ratio may be maximized. As the initial condition for setting the cell boundary, a particular value of the cross-talk (e.g., 1-5%) between the neighboring elements may be used, and on the second step the collection efficiency to cross-talk ratio may be maximized by shifting the boundary back and forth along a direction connecting the neighboring elements. In some instances, the cell shape may be defined not only by the four nearest neighbors, but by additional gaps along the diagonals which may be used to minimize cross-talk (see FIG. 11B). These new boundaries (shown by dotted lines in FIG. 11B) may define additional spacing along the diagonal directions and will cut the corners of the cells.

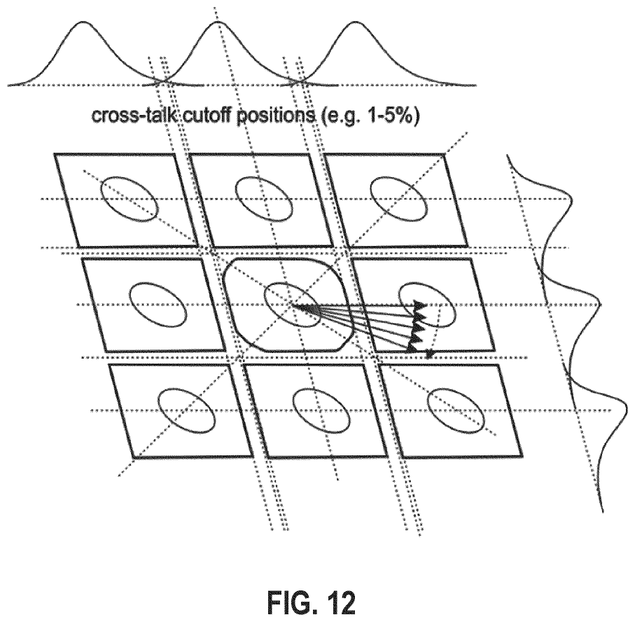

Reference is now made to FIG. 12, which illustrates an approach of determining detector cell shape and size, consistent with embodiments of the disclosure. A general approach for defining the shape of the cells on a pixelated detector may be represented by FIG. 12. A procedure for determining the cell shape and size may include:
Rays from the spot center are drawn in all possible directions;
For each ray the cross-section of the 2D spot distribution is calculated, and the cell boundary is set according to the targeted cross-talk value;
The collection efficiency to cross-talk ratio is maximized by shifting the cell boundary back and forth along the ray direction;
After finding the cell boundaries in all directions for all detector cells, the most general form of detector cells may be determined for the pixelated detector.

Parameters of beam spots on a detector may be controlled using components of a secondary imaging system. For example, secondary imaging system 6 may include components that influence beams traveling through secondary imaging system and that have an effect on the size and shape of beam spots formed at the surface of detector 7. Projection lens 152 may perform an anti-rotation function and may be used to orient the spot array on the detector. In some embodiments, objective lens 131 may include magnetic elements, and beams passing through objective lens 131 may experience a rotation due to magnetic field generated by objective lens 131. The rotation may be about primary optical axis 100_1. Projection lens 152 may be configured to cancel rotation that may be due to objective lens 131. Projection lens 152 may include magnetic elements (e.g., a magnetic lens), and may rotate beams passing through projection lens 152. The rotation may be about secondary optical axis 150_1. Rotation induced by projection lens 152 may be opposite in direction to that induced by objective lens 131. In some embodiments, projection lens 152 may be configured to allow a predetermined amount of rotation.

Other components of a charged particle beam system may also induce rotation at various points in the system.

Secondary imaging system 6 may be configured to control shape and size of beam spots projected on detector 7, or other parameters. A target shape of beam spots may be elliptical, and the elliptical shape may be tilted (e.g., aligned with a diagonal direction with respect to detector cells). Projection lens 152 may be configured to form beam spots on detector 7 with a tilted elliptical shape by controlling a magnetic field generated by projection lens 152. In some embodiments, an arrangement of detector cells on detector 7 may be offset (see FIG. 10B, FIG. 11A, FIG. 11B, and FIG. 12). Projection lens 152 may be configured to form beam spots on detector 7 in an array pattern that is rotated so as to match an offset arrangement of detector cells. Stigmator 9 may be configured to adjust shape and orientation of beam spots on detector 7.

Zoom lens 151 may perform a focusing function. Zoom lens 151, projection lens 152, and stigmator 9 may work together to adjust a focus of beams passing through secondary imaging system 6 and may form focused beam spot images on detector 7. Components of secondary imaging system 6 may be adjusted to control focusing of beams passing through secondary imaging system 6. Focusing may be adjusted so as to form beam spots with a target shape. For example, focusing may be adjusted so as to form elliptical beam spots.

Control of components of secondary imaging system 6 may be based on a deflection setting. The deflection setting may be of scanning deflection unit 132, or anti-scanning deflection unit 157, for example. Control of focusing and rotation, for example using zoom lens 151, projection lens 152, and stigmator 9 of secondary imaging system 6, may be done in step with performing anti-scanning using anti-scanning deflection unit 157.

In some embodiments, a multi-beam charged particle beam apparatus may be used. In some embodiments, a single-beam charged particle beam apparatus may be used. A single-beam system may also use a scanning deflector. In a comparative embodiment, no anti-scanning deflector is used, and secondary particles are collected by a detector that may have a single detector cell. However, the spread of particles impacting the detector may be broad, and thus a large detector may be needed. In some embodiments of the disclosure, an anti-scanning deflector may be used, and the spread of particles impacting the detector may be made smaller. Furthermore, a secondary imaging system may be used, and components of the secondary imaging system may be operated in anti-scanning mode. The spread of particles may be further made smaller by reducing distortion of a beam spot formed on the detector. Some embodiments of the disclosure may enable miniaturization of a detector, or other components.

A method of correcting focus of beam may comprise adjusting an excitation of a component of a secondary imaging system of a charged particle beam apparatus. The beam may be a secondary beam or a plurality of secondary beamlets. The beam may be defocused as a result of anti-scanning deflection of the beam. The beam may pass through the secondary imaging system. The beam may pass through the secondary imaging system en route to a detector or some other component (e.g., a transfer lens).

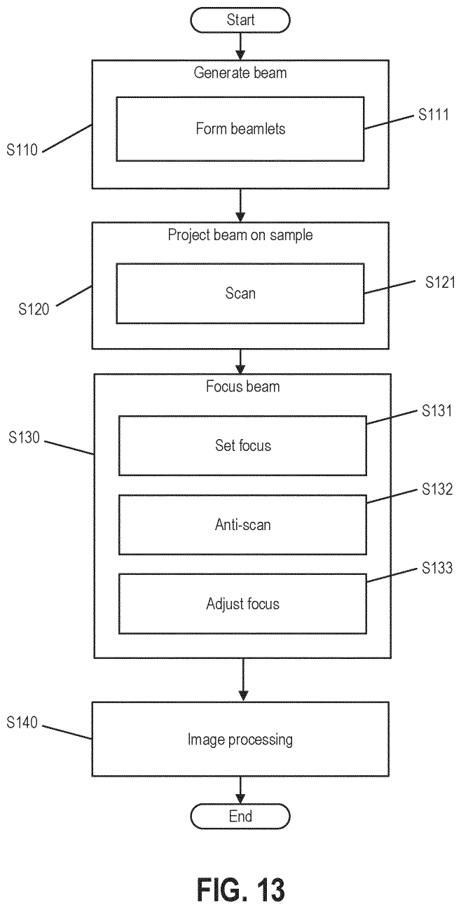

FIG. 13 is a flowchart illustrating an exemplary method of correcting focus of a beam, consistent with embodiments of the present disclosure. The method of FIG. 13 may be performed by controller 109 of EBI system 10, as shown in FIG. 1, for example. Controller 109 may be programmed to implement one or more blocks of the flowchart illustrated in FIG. 13. For example, controller 109 may instruct a module of a charged particle beam system to generate a charged particle beam and carry out other functions. Controller 109 may control actuation of beam separator 160, scanning deflection unit 132, or secondary imaging system 6.

A method consistent with FIG. 13 may begin with a first step S110 of generating a charged particle beam by a charged particle beam source. For example, a primary beam source that includes an anode and cathode may generate a charged particle beam, as shown in FIG. 2. First step S110 may include a step S111 of forming beamlets. A plurality of beamlets (e.g., beamlets 102_1, 102_2, and 102_3 may be formed from a primary beam (e.g., primary beam 102).

As shown in FIG. 13, a second step S120 may be performed. Second step S120 may include projecting a beam on a sample. The beam may be that generated in first step S110. Second step S120 may be performed using components of a primary column of a charged particle beam apparatus. For example, objective lens 131 may be used to project the beam onto sample 8. Second step S120 may include a step S121 of scanning the beam across the surface of the sample. Second step S120 may include using scanning deflection unit 132 to perform scanning on sample 8. The beam may be deflected as scanning is performed. There may be a deflection setting of scanning deflection unit 132 corresponding to performing scanning. For example, a first deflection setting may correspond to a beam being in position C1 (see FIG. 6), and a second deflection setting may correspond to a beam being in position C2 (see FIG. 6).

Furthermore, as shown in FIG. 13, a third step S130 may be performed. Third step S130 may include focusing a beam so that a beam spot is projected onto a detector. The beam may be a secondary beam generated from projection of the beam of step S120 on the sample, and a beam spot being formed on the sample from which the secondary beam is generated. The secondary beam may include a plurality of secondary beamlets. Third step S130 may include a step S131 of setting a focus of the beam. Step S131 may include setting an initial focus of the beam that is based on an undeflected state of the beam. In some embodiments, step S131 may include setting a focus that is based on an initial deflection setting of the beam. The deflection setting of the beam may correspond to that used in step S121. Third step S130 may also include a step S132 of performing anti-scanning. Step S132 may be performed by an anti-scanning deflection unit of a secondary imaging system (e.g., anti-scanning deflection unit 157 of FIGS. 3A-3G). Anti-scanning of step S132 may be performed in step with scanning of step S121. Third step S130 may also include a step S133 of adjusting focus. The focus of the beam set in step S131 may be adjusted. Step S133 may include adjusting an excitation of a component of the secondary imaging system. The component may include a plurality of components. The component may include a lens. Step S133 may include changing a voltage or current applied to a lens. In some embodiments, the component may include an electrostatic lens, and step 133 may include adjusting a voltage applied to an electrode of the electrostatic lens.

Step S133 of adjusting excitation of the component may compensate for a reduction in focus of the beam due to the beam having been deflected. The reduction in focus of the beam may be due to the beam passing through an anti-scanning deflector (e.g., an anti-scanning deflection unit of the secondary imaging system). The reduction in focus of the beam may be due to the beam originating from a probe spot position on a sample that is different from an undeflected beam (e.g., a beam that has not undergone deflection for scanning, or a beam that is in a base position of a scan) (see undeflected position A vs. deflected position B in FIG. 5B).

Step S133 of adjusting excitation of the component may be done synchronously with step S132 of performing anti-scanning. For example, as a beam is shifted by anti-scanning in a secondary imaging system, a component of the secondary imaging system (such as a lens) may have its excitation adjusted. Adjusting of excitation may be performed with high frequency, similar to scanning or anti-scanning operations. Excitation of the component of the secondary imaging system may be updated continuously as scanning or anti-scanning is performed.

Step S133 of adjusting excitation of the component may be done so as to achieve a target parameter of a beam spot formed on the detector. The target parameter may include size, shape, or arrangement (e.g., orientation) of the beam spot. For example, step S133 may include adjusting excitation of the component so as to form elliptical beam spots that are aligned with a diagonal direction of a detector cell of the detector.

In step S133, the component may include multiple components, and excitation applied to each of the multiple components may be adjusted.

Also as shown in FIG. 13, a fourth step S140 of imaging processing may be performed. As a result of focusing performed in third step S130, beam spots may be formed on the detector, and the detector may generate an imaging signal. The imaging signal may be processed, and an image of the sample surface under inspection may be generated. Fourth step S140 may also include performing optimization of a parameter of beam spots formed on the detector, or optimization of a parameter of detector cells of the detector. The method of FIG. 13 may be performed iteratively, and the parameter may be adjusted as beam focus is repeatedly adjusted. In some embodiments, it may be known in advance what excitation of the component of the secondary imaging system corresponds to achieving the target parameter of the beam spot formed on the detector. In some embodiments, step S133 of adjusting excitation of the component may be done without a feedback loop. Furthermore, a step of setting a parameter of a detector (e.g., size, shape, or arrangement of detector cells) may be performed independent or in advance of the method of FIG. 13.

A parameter of beam spots may include beam spot size, shape, or arrangement, for example. Beam spot size may include a radius of a beam spot. In the case of beam spots having shapes other than circular, beam spot size may include other measures of size, such as a major or minor axis of an ellipse. Beam spot size may include an area of the beam spot.

Beam spot shape may be circular or some shape other than circular. In some embodiments, using elongated beam spots, such as elliptical beam spots, may help to enhance collection efficiency and reduce cross-talk. Using an elongated beam spot may allow relaxation of certain imaging conditions, as it may become acceptable for some types of distortion to occur (e.g., astigmatism, or coma effects). Elongated beam spots may be allowed to be distorted from a circular shape while still being contained within the area of a detector cell. Still, optimization of the precise shape of beam spots may be helpful to maximize collection efficiency and minimize cross-talk.

Furthermore, arrangement of the beam spots may include orientation, pattern, spacing, or rotation of the beam spots. Arrangement of beam spots may be based on parameters of detector cells of the detector, such as size, shape, and arrangement of the detector cells. Elongated beam spots may be oriented so that their elongated direction is aligned with the longest dimension of the detector cells. Detector cells may be square, and the elongated direction of the elongated beam spots may be aligned with the diagonal of the square detector cell. Detector cells may be rectangular. Furthermore, a scaling factor may be determined between the major and minor axis of the elliptical or elongated shape of beam spots. In some embodiments, an array of detector cells may be provided, and the elongated direction of the elongated beam spots may be aligned with a line connecting neighboring lattice elements of the detector (see FIG. 10B). In such a case, the line connecting neighboring lattice elements of the detector may not necessarily align with the longest dimension of individual detector cells. In some embodiments, beam spots may be asymmetrical. In some embodiments, there may be gaps between neighboring detector cells. Optimizing a parameter of a detector may include determining a gap between neighboring detector cells that may be based on cross-talk cutoff positions.

A method of optimizing a parameter of a beam spot may comprise determining an elongated shape of the beam spot and determining an orientation of the beam spot. The beam spot may be elongated so as to have a long direction and a short direction. The long direction may be oriented based on a shape of a corresponding detector cell of the detector. The long direction may be oriented so as to align with the longest dimension of the detector cell (e.g., the diagonal of a square or rectangular detector cell). In some embodiments, determining shape or orientation may be based on arrangement of detector cells in an array. In some embodiments, determining shape or orientation may be based on asymmetric properties of the beam spot.

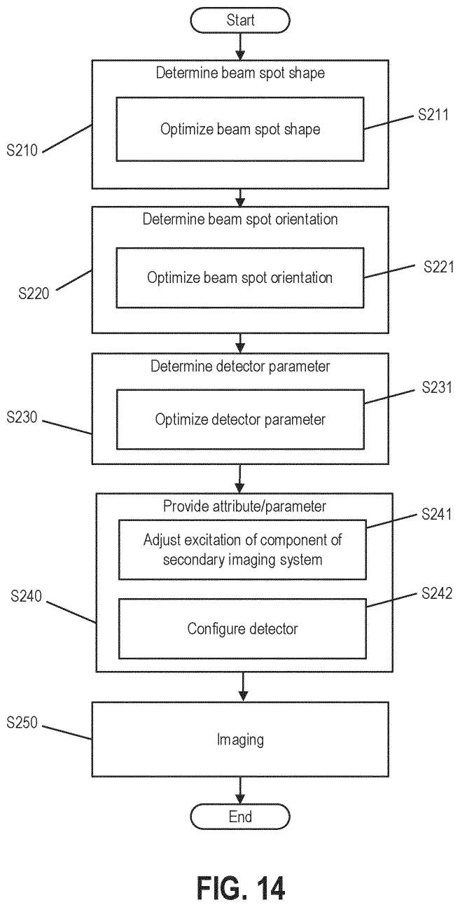

FIG. 14 is a flowchart illustrating an exemplary method of optimizing a parameter of a beam spot or detector cell, consistent with embodiments of the present disclosure. The method of FIG. 14 may be performed by controller 109 of EBI system 10, as shown in FIG. 1, for example. Controller 109 may be programmed to implement one or more blocks of the flowchart illustrated in FIG. 14. For example, controller 109 may instruct a module of a charged particle beam system to set or adjust excitation of a component of a secondary imaging system, configure a detector, and carry out other functions.

A method consistent with FIG. 14 may begin with a first step S210 of determining beam spot shape. First step S210 may include determining an elongated shape for the beam spot. The elongated shape may be an ellipse. In some embodiments, the elongated shape may be asymmetric. First step S210 may include step S211 of optimizing beam spot shape. Optimizing may be based on minimizing cross-talk, maximizing collection efficiency, or achieving a predetermined ratio of collection efficiency to cross-talk, for example. Optimization may be based on an expected beam projection pattern and detector configuration. Optimization may aim to change a shape of beam spots from that shown in FIG. 7B to that shown in FIG. 7C, for example, or some other shape that improves performance based on collection efficiency or cross-talk.

As shown in FIG. 14, a second step S220 may be performed. Second step S220 may include projecting determining beam spot orientation. Beam spot orientation may be determined to be aligned with a long dimension of a detector cell. Beam spot orientation may be determined to be aligned with a diagonal direction of the detector cell. Second step S220 may include a step S221 of optimizing beam spot orientation. Step S221 may be performed together with step S211.

Furthermore, a third step S230 of determining a parameter of a detector may be performed. In some embodiments, a detector configuration may be predetermined. A detector may be fixed and its detector cells may not be adjustable. In some embodiments, for example, a pixelated detector may be used, and detector cells of the detector may be adjustable. Third step S230 may include a step S231 of optimizing the parameter of the detector. The parameter may include size, shape, arrangement, etc. of the detector cells of the detector.

The method of FIG. 14 may include a fourth step S240 of providing the parameter or parameter determined in previous steps. For example, the parameter of the beam spot or the parameter of the detector may be provided to a charged particle beam apparatus. Fourth step S240 may include a step S241 of adjusting excitation of a component of a secondary imaging system of the charged particle beam apparatus. Step S241 may include step S133 of FIG. 13, for example. Fourth step S240 may include a step 242 of configuring a detector of the charged particle beam apparatus. Step S242 may include setting a size, shape, or arrangement of detector cells of the detector.

The method of FIG. 14 may also include a fifth step S250 of performing imaging. Fifth step S250 may include using the primary beam of a charged particle beam apparatus to irradiate a sample.

In some embodiments, a controller may control a charged particle beam system. The controller may include a computer processor. The controller may instruct components of the charged particle beam system to perform various functions, such as controlling a charged particle source to generate a charged particle beam and controlling deflectors of a deflector array to deflect beams. The controller may also perform functions of determining focusing values in a secondary imaging system, determining scanning and anti-scanning, adjusting focusing values in the secondary imaging system, performing image processing, etc. The controller may comprise a storage that is a storage medium such as a hard disk, cloud storage, random access memory (RAM), other types of computer readable memory, and the like. The controller may communicate with a cloud storage. A non-transitory computer readable medium may be provided that stores instructions for a processor (e.g., a processor of controller 109) to carry out beam focusing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. For example, step S132 of anti-scanning and step S133 of adjusting focus may occur in an order that may be determined by an arrangement of components in a secondary imaging system. For example, when an anti-scanning deflector is upstream from a component of the secondary imaging system to be adjusted, step S132 may be performed before step S133. When the anti-scanning deflector is downstream from the component of the secondary imaging system to be adjusted, step S133 may be performed before step S132. When multiple components are to be adjusted, and the anti-scanning deflector is between the components, some steps of adjusting focus may be performed before anti-scanning, and some steps of adjusting focus may be performed after performing anti-scanning. In some embodiments, step S132 of anti-scanning and step S133 of adjusting focus may be performed simultaneously. Furthermore, steps such as compensating for astigmatism, or other distortion, may be added. It should also be understood that each block of the block diagrams, and combination of the blocks, may be implemented by special purpose hardware-based systems that perform the specified functions or acts, or by combinations of special purpose hardware and computer instructions.

The embodiments may further be described using the following clauses:
1. A method of correcting focus of a secondary beam defocused due to anti-scanning deflection of the secondary beam, the method comprising:
adjusting an excitation of a component of a secondary imaging system based on a deflection setting of an anti-scanning deflector, the secondary beam passing through the secondary imaging system,
wherein the adjusting compensates for a reduction in focus of the secondary beam due to the secondary beam passing through the anti-scanning deflector.
2. The method of clause 1, wherein the component includes a lens of the secondary imaging system, and the adjusting includes changing a voltage or current applied to the lens.
3. The method of clause 2, wherein the lens includes an electrostatic lens.
4. The method of any of clauses 1-3, wherein the component includes electrostatic lenses of a zoom lens or a projection lens.
5. The method of any of clauses 1-4, wherein the component includes a stigmator.
6. The method of any of clauses 1-5, wherein the secondary beam includes a plurality of beamlets.
7. The method of any of clauses 1-6, wherein the excitation is adjusted so as to form a beam spot on a detector with a target parameter.
8. The method of clause 7, wherein the target parameter includes a size of the beam spot.
9. The method of clause 7 or clause 8, wherein the target parameter includes a shape of the beam spot.
10. The method of clause 9, wherein the shape of the beam spot is elongated.
11. The method of clause 10, wherein the shape of the beam spot is elliptical.
12. The method of any of clauses 7-11, wherein the target parameter includes an orientation of the beam spot.
13. The method of clause 12, wherein the orientation of the beam spot is aligned with a long dimension of a detector cell of the detector.
14. The method of clause 12, wherein the orientation of the beam spot is aligned with a diagonal direction of a detector cell of the detector.
15. The method of any of clauses 1-14, wherein the excitation of the component is adjusted so as to minimize cross-talk.
16. The method of any of clauses 1-14, wherein the excitation of the component is adjusted so as to maximize collection efficiency.
17. The method of any of clauses 1-14, wherein the excitation of the component is adjusted so as to achieve a predetermined ratio of collection efficiency to cross-talk.
18. The method of any of clauses 1-17, wherein the excitation of the component is adjusted based on size, shape, or arrangement of detector cells.
19. The method of any of clauses 1-18, wherein the excitation of the component is adjusted synchronously with anti-scanning performed by the anti-scanning deflector.
20. The method of any of clauses 1-19, wherein the excitation of the component is adjusted synchronously with scanning performed by a scanning deflector.
21. A computer readable medium storing a set of instructions that are executable by one or more processors of a system to cause the system to perform a method comprising:
adjusting an excitation of a component of a secondary imaging system based on a deflection setting of an anti-scanning deflector, the secondary imaging system configured to influence a secondary beam passing through the secondary imaging system,
wherein the adjusting compensates for a reduction in focus of the secondary beam due to the secondary beam passing through the anti-scanning deflector.
22. The medium of clause 21, wherein the component includes a lens of the secondary imaging system, and the adjusting includes changing a voltage or current applied to the lens.
23. The medium of clause 22, wherein the lens includes an electrostatic lens.
24. The medium of any of clauses 21-23, wherein the component includes electrostatic lenses of a zoom lens or a projection lens.
25. The medium of any of clauses 21-24, wherein the component includes a stigmator.
26. The medium of any of clauses 21-25, wherein the secondary beam includes a plurality of beamlets.
27. The medium of any of clauses 21-26, wherein the excitation is adjusted so as to form a beam spot on a detector with a target parameter.
28. The medium of clause 27, wherein the target parameter includes a size of the beam spot.
29. The medium of clause 27 or clause 28, wherein the target parameter includes a shape of the beam spot.
30. The medium of clause 29, wherein the shape of the beam spot is elongated.
31. The medium of clause 10, wherein the shape of the beam spot is elliptical.
32. The medium of any of clauses 27-31, wherein the target parameter includes an orientation of the beam spot.
33. The medium of clause 32, wherein the orientation of the beam spot is aligned with a long dimension of a detector cell of the detector.
34. The medium of clause 32, wherein the orientation of the beam spot is aligned with a diagonal direction of a detector cell of the detector.
35. The medium of any of clauses 21-34, wherein the excitation of the component is adjusted so as to minimize cross-talk.
36. The medium of any of clauses 21-34, wherein the excitation of the component is adjusted so as to maximize collection efficiency.
37. The medium of any of clauses 21-34, wherein the excitation of the component is adjusted so as to achieve a predetermined ratio of collection efficiency to cross-talk.
38. The medium of any of clauses 21-37, wherein the excitation of the component is adjusted based on a size, a shape, or an arrangement of detector cells.
39. The medium of any of clauses 21-38, wherein the excitation of the component is adjusted synchronously with anti-scanning performed by the anti-scanning deflector.
40. The medium of any of clauses 21-39, wherein the excitation of the component is adjusted synchronously with scanning performed by a scanning deflector.
41. A method of operating a secondary imaging system of a charged particle beam apparatus, comprising:
performing scanning of a primary beam on a sample;
performing anti-scanning of a secondary beam generated from incidence of the primary beam on the sample; and
adjusting an excitation of a component of the secondary imaging system while performing the anti-scanning.
42. The method of clause 41, wherein the excitation of the component is adjusted simultaneously with performing the anti-scanning.
43. The method of clause 41 or clause 42, wherein the excitation is adjusted based on a deflection setting of an anti-scanning deflector performing the anti-scanning.
44. The method of any of clauses 41-43, wherein the component includes a lens of the secondary imaging system, and the adjusting includes changing a voltage or current applied to the lens.
45. The method of clause 44, wherein the lens includes an electrostatic lens.
46. The method of any of clauses 41-45, wherein the component includes electrostatic lenses of a zoom lens or a projection lens.
47. The method of any of clauses 41-46, wherein the component includes a stigmator.
48. The method of any of clauses 41-47, wherein the secondary beam includes a plurality of secondary beamlets.
49. The method of any of clauses 41-48, wherein the excitation is adjusted so as to form a secondary beam spot on a detector with a target parameter.
50. The method of any of clauses 41-49, wherein the primary beam includes a plurality of primary beamlets.
51. A computer readable medium storing a set of instructions that are executable by one or more processors of a system to cause the system to perform a method comprising:
performing scanning of a primary beam of a charged particle beam apparatus on a sample;
performing anti-scanning of a secondary beam generated from incidence of the primary beam on the sample;
adjusting an excitation of a component of a secondary imaging system of the charged particle beam apparatus while performing the anti-scanning.
52. The medium of clause 51, wherein the excitation of the component is adjusted simultaneously with performing the anti-scanning.
53. The medium of clause 51 or clause 52, wherein the excitation is adjusted based on a deflection setting of an anti-scanning deflector performing the anti-scanning.
54. The medium of any of clauses 51-53, wherein the component includes a lens of the secondary imaging system, and the adjusting includes changing a voltage or current applied to the lens.
55. The medium of any of clauses 51-54, wherein the component includes a lens of the secondary imaging system, and the adjusting includes changing a voltage or current applied to the lens.
56. The medium of any of clauses 51-55, wherein the component includes an electrostatic lens.
57. The medium of any of clauses 51-56, wherein the component includes electrostatic lenses of a zoom lens or a projection lens.
58. The medium of any of clauses 51-57, wherein the component includes a stigmator.
59. The medium of any of clauses 51-58, wherein the secondary beam includes a plurality of beamlets.
60. The medium of any of clauses 51-59, wherein the excitation is adjusted so as to form a beam spot on a detector with a target parameter.
61. A charged particle beam apparatus comprising:
a charged particle beam source configured to generate a primary beam;
a scanning deflector configured to perform scanning of the primary beam on a sample; and
a secondary imaging system that includes:
   an anti-scanning deflector configured to perform anti-scanning of a secondary beam generated from incidence of the primary beam on the sample; and
   a component configured to control focusing of the secondary beam so as to compensate for reduction in focus of the secondary beam due to the secondary beam originating from deflected positions on the sample.
62. The apparatus of clause 61, wherein the primary beam includes a plurality of primary beamlets, the secondary beam includes a plurality of secondary beamlets, and the component includes a lens of the secondary imaging system.
63. A method of optimizing a parameter of a secondary beam spot on a detector of a charged particle beam apparatus, the method comprising:
determining the parameter based on collection efficiency or cross-talk for a detector cell of the detector;
providing the parameter to the charged particle beam apparatus; and
adjusting excitation of a component of a secondary imaging system of the charged particle beam apparatus based on the parameter.
64. The method of clause 63, wherein the parameter comprises a size, a shape, or an arrangement of the beam spot on the detector, the method further comprising:
determining an elongated shape of the beam spot;
determining an orientation of the beam spot such that an elongated direction of the beam spot is aligned with a direction of the detector cell; and
determining the parameter so as to maximize the collection efficiency, minimize the cross-talk, or achieve a predetermined ratio of the collection efficiency to the cross-talk.
65. A computer readable medium storing a set of instructions that are executable by one or more processors of a system to cause the system to perform a method comprising:
determining a parameter of a secondary beam spot on a detector of a charged particle beam apparatus based on collection efficiency or cross-talk for a detector cell of the detector;
providing the parameter to the charged particle beam apparatus; and
adjusting excitation of a component of a secondary imaging system of the charged particle beam apparatus based on the parameter.
66. A method of optimizing a parameter of a detector of a charged particle beam apparatus, the method comprising:
determining a shape of a secondary beam spot on the detector;
determining an orientation of the beam spot relative to detector cells of the detector;
determining the parameter based on collection efficiency or cross-talk for a detector cell of the detector;
providing the parameter to the charged particle beam apparatus; and
configuring the detector based on the parameter.
67. The method of clause 66, further comprising:
optimizing the parameter so as to maximize the collection efficiency, minimize the cross-talk, or achieve a predetermined ratio of the collection efficiency to the cross-talk.
68. The method of clause 66 or clause 67, further comprising:
determining a gap between neighboring detector cells of the detector.
69. A computer readable medium storing a set of instructions that are executable by one or more processors of a system to cause the system to perform a method comprising:
determining a shape of a secondary beam spot on the detector;
determining an orientation of the beam spot relative to detector cells of the detector;
determining the parameter based on collection efficiency or cross-talk for a detector cell of the detector;
providing the parameter to the charged particle beam apparatus; and
configuring the detector based on the parameter.

It will be appreciated that the embodiments of the present disclosure are not limited to the exact construction that has been described above and illustrated in the accompanying drawings, and that various modifications and changes can be made without departing from the scope thereof. For example, one or more lenses or other optical components may be added at various points to the particular constructions of exemplary particle-optical system discussed herein. Optical components may be provided for, e.g., magnifying, zooming, and image anti-rotating etc.

1. A method of correcting focus of a secondary beam defocused due to anti-scanning deflection of the secondary beam, the method comprising:
adjusting an excitation of a component of a secondary imaging system based on a deflection setting of an anti-scanning deflector, the secondary beam passing through the secondary imaging system,
wherein the adjusting compensates for a reduction in focus of the secondary beam due to the secondary beam passing through the anti-scanning deflector.

2. A computer readable medium storing a set of instructions that are executable by one or more processors of a system to cause the system to perform a method comprising:
adjusting an excitation of a component of a secondary imaging system based on a deflection setting of an anti-scanning deflector, the secondary imaging system configured to influence a secondary beam passing through the secondary imaging system,
wherein the adjusting compensates for a reduction in focus of the secondary beam due to the secondary beam passing through the anti-scanning deflector.

3. The medium of claim 2, wherein the component includes a lens of the secondary imaging system, and the adjusting includes changing a voltage or current applied to the lens.

4. The medium of claim 3, wherein the lens includes an electrostatic lens.

5. The medium of claim 2, wherein the component includes electrostatic lenses of a zoom lens or a projection lens.

6. The medium of claim 2, wherein the component includes a stigmator.

7. The medium of claim 2, wherein the secondary beam includes a plurality of beamlets.

8. The medium of claim 2, wherein the excitation is adjusted so as to form a beam spot on a detector with a target parameter.

9. The medium of claim 8, wherein the target parameter includes a size of the beam spot.

10. The medium of claim 8, wherein the target parameter includes a shape of the beam spot.

11. The medium of claim 10, wherein the shape of the beam spot is elongated.

12. The medium of claim 10, wherein the shape of the beam spot is elliptical.

13. The medium of claim 8, wherein the target parameter includes an orientation of the beam spot.

14. The medium of claim 13, wherein the orientation of the beam spot is aligned with a long dimension of a detector cell of the detector.

15. The medium of claim 14, wherein the orientation of the beam spot is aligned with a diagonal direction of a detector cell of the detector.

16. The medium of claim 2, wherein the excitation of the component is adjusted so as to minimize cross-talk.

17. The medium of claim 2, wherein the excitation of the component is adjusted so as to maximize collection efficiency.

18. The medium of claim 2, wherein the excitation of the component is adjusted so as to achieve a predetermined ratio of collection efficiency to cross-talk.

19. The medium of claim 2, wherein the excitation of the component is adjusted based on a size, a shape, or an arrangement of detector cells.

20. The medium of claim 2, wherein the excitation of the component is adjusted synchronously with anti-scanning performed by the anti-scanning deflector.
